(19) United States
(12) Patent Application Publication
(10) Pub. No.: US 2010/0300529 A1
(43) Pub. Date: Dec. 2, 2010

(54) DYE-SENSITIZED SOLAR CELL

(75) Inventors: Yusuke Kawahara, Saitama (JP); Hirokazu Koyama, Tokyo (JP); Takahiro Nojima, Tokyo (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA HOLDINGS, INC., Tokyo (JP)

(21) Appl. No.: 12/811,160

(22) PCT Filed: Dec. 10, 2008
(86) PCT No.: PCT/JP2008/072409

§ 371 Date: Jun. 29, 2010

(30) Foreign Application Priority Data
Jan. 8, 2008 (JP) 2008001061

(51) Int. Cl. H01L 31/0296; H01L 31/0224

(52) U.S. Cl. 136/256; 257/E31.015; 257/E31.126

(57) ABSTRACT

Disclosed is a dye-sensitized solar cell which can simultaneously realize an excellent photoelectric conversion efficiency and excellent durability. The dye-sensitized solar cell is also suitable when a resin film is used as a base material. The dye-sensitized solar cell comprises an electroconductive base material, and a metal oxide semiconductor layer formed of a semiconductor film with a dye adsorbed on the surface thereof, a charge transfer layer, and a counter electrode provided in that order on the electroconductive base material and is characterized in that a metal oxide intermediate layer formed of fine particles of a metal oxide is provided between the electroconductive base material and the metal oxide semiconductor layer and the electroconductive base material comprises a transparent base material, and a metallic current collecting layer formed of metallic fine wires and an electroconductive polymer-containing transparent electroconductive layer provided on the transparent base material.

### TECHNICAL FIELD

The present invention relates to a dye-sensitized solar cell. In particular, the present invention relates to a dye-sensitized solar cell which is excellent in photoelectric conversion efficiency and has improved durability.

### BACKGROUND

In recent years, there has been paid attention to a dye-sensitized solar cell as a solar cell using an organic material which will replace a silicon system solar cell, and research and development have been done extensively.

The operation principle of a common dye-sensitized solar cell is as follows. When the sensitizing dye which is adsorbed to a metal oxide semiconductor electrode absorbs solar light, an excited electron is generated, and the excited electron moves to a metal oxide semiconductor, and also it moves to a counter electrode through the circuit which connects an electrode via a transparent conductive film. The electron which has moved to the counter electrode reduces an electrolyte, and the electrolyte will reduce the sensitizing dye which has become in the oxidation state after releasing an electron.

In the conventional dye-sensitized solar cell, since a metal oxide semiconductor layer is porous, the electrolyte is in contact with the transparent conductive film. Therefore, there will occur a reverse electronic transfer in which an excited electron will be poured from a transparent conductive film to an electrolyte, this will cause a problem that an open circuit voltage will be decreased, and as a result, photoelectric conversion efficiency will be fallen. Moreover, when an electrolyte containing iodine redox was used, since the electrolyte was in contact with the transparent conductive film, there occurred also a problem that a conductive film corroded and durability was deteriorated by the electrolyte.

In order to resolve these problems, there were disclosed technologies by which a reverse electronic transfer was prevented and photoelectric conversion efficiency was improved. These technologies are to provide a dense layer which is mainly composed of a metal oxide between a transparent conductive film and a metal oxide semiconductor layer (for example, refer to Patent documents 1 and 2). However, with these technologies, although a reverse electronic transfer was able to be prevented, they have not resulted in the satisfactory photoelectric conversion efficiency because they had insufficient means to pass efficiently the electron which was transferred normally and reached the electrode to an external circuit.

On the other hand, in the conventional dye-sensitized solar cell, metal oxide thin films, such as indium doped tin oxide (ITO) and fluorine doped tin oxide (FTO), are formed with vacuum deposition, sputtering process on the base as a transparent conductive film. However, in this conventional transparent conductive film, a material cost and a manufacturing cost were expensive, and also there was a problem that the above-mentioned metal oxide which constituted a transparent conductive film had a defect of extremely high resistibility compared with a metal, and it became a cause which decreased the photoelectric conversion efficiency in a solar cell. Although low efficiency can be reduced by thickening a transparent conductive film, a light transmittance will fall and also it will cause increase of a material cost and a manufacturing cost by this.

As a means to resolve such problems, there were proposed technologies in which a metallic current collecting thin layer was provided, such as a mesh form, as a transparent conductive film to increase the conductivity of an electrode and also to prevent corrosion of the metal by the electrolyte (for example, refer to Patent documents 3 and 4). However, although improvement of the conductivity and prevention of corrosion can be achieved to some extent with these technologies, they were not fully satisfied.

Furthermore, the surface smoothness of a transparent conductive film was not fully controlled, and an excellent photoelectric conversion efficiency has not been achieved due to the loss of the file factor. Moreover, these methods for forming a metallic current colleting thin layer cannot always be applied when particularly a resin film is used instead of a glass base. There is a case in which these methods are not applicable for producing a flexible dye-sensitized solar cell.

Patent document 1: Japanese Patent Application Publication (JP-A) No. 2002-75471

Patent document 2: JP-A No. 2002-151168

Patent document 3: WO 04/86464

Patent document 4: JP-A No. 2007-42366

### DISCLOSURE OF THE INVENTION

### Problems to be Solved by the Invention

The present invention was made in order to resolve the problems which were mentioned above. An object of the present invention is to provide a dye-sensitized solar cell which can realize excellent photoelectric conversion efficiency and can achieve excellent durability by preventing the reverse electronic transfer and by improving the conductivity of an electrode. Another object of the present invention is to provide a dye-sensitized solar cell which is suitable when a resin film is used as a base material.

### Means to Solve the Problems

The problem of the present invention has been resolved by providing an improved transparent conductive layer which has a metal oxide inter layer, and also, has a metallic current collecting layer. Specific embodiments are described below.
1. A dye-sensitized solar cell comprising a conductive base having thereon a metal oxide semiconductor layer composed of a semiconductor film which is adsorbed a dye on a surface of the semiconductor film; a charge transfer layer; and a counter electrode in that order,

wherein a metal oxide interlayer composed of metal oxide particles is provided between the conductive base and the metal oxide semiconductor layer, and the conductive base comprises a transparent base having thereon a metallic current collecting layer composed of metallic thin wires and a transparent conductive layer containing a conductive polymer.
2. The dye-sensitized solar cell of the above-described item 1,

wherein the metallic thin wire has a line width of 5 μm to 20 μm, and the metallic current collecting layer has an aperture ratio of 93% to 98%.
3. The dye-sensitized solar cell of the above-described items 1 or 2,

wherein the transparent conductive layer covers an aperture portion of the metallic current collecting layer and an upper portion of the metallic thin wires, and the uppermost surface of the conductive base is smooth.
4. The dye-sensitized solar cell of any one of the above-described items 1 to 3,

wherein the metal oxide interlayer has a thickness of 5 nm to 200 nm.
5. The dye-sensitized solar cell of any one of the above-described items 1 to 4,

wherein the metal oxide interlayer has a porous ratio of 10% or less.

### Effects of the Invention

According to the present invention, it was possible to provide a dye-sensitized solar cell which can realize excellent photoelectric conversion efficiency and can achieve excellent durability. Further, it was possible to provide a dye-sensitized solar cell which is suitable when a resin film is used as a base material.

### BRIEF DESCRIPTION OF THE DRAWING

FIG. 1 is a schematic cross-sectional view showing a basic structure of a dye-sensitized solar cell of the present invention.

### DESCRIPTION OF SYMBOLS

10: Transparent conductive layer

11: Metallic current collecting layer

20: Metal oxide semiconductor layer

30: Charge transfer layer

40: Conductive layer (counter electrode)

50: Base

50a: Transparent base

60: Metal oxide interlayer

### DESCRIPTION OF THE PREFERRED EMBODIMENTS

Hereafter, the present invention will be described in detail.

### <<Dye-Sensitized Solar Cell>>

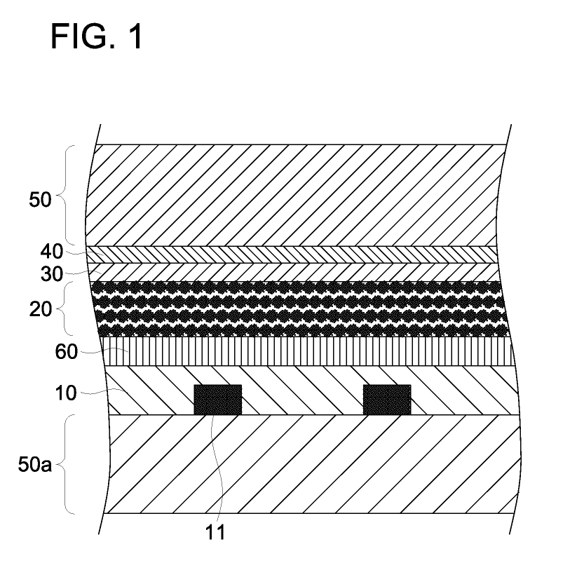

First, the dye-sensitized solar cell of the present invention will be described by referring to FIG. 1. FIG. 1 is a schematic cross-sectional view showing the basic structure of the dye-sensitized solar cell of the present invention. The dye-sensitized solar cell of the present invention has a composition as shown by FIG. 1. It contains transparent base 50a as a conductive base having thereon metallic current collecting layer 11 and transparent conductive layer 10. On the transparent conductive layer 10, it contains metal oxide interlayer 60, metal oxide semiconductor layer 20 composed of a semiconductor film which is adsorbed a dye on a surface of the semiconductor layer, and charge transfer layer 30 (it is also called as “electrolyte layer”) in that order, and also it has conductive layer 40 as a counter electrode on a surface of base 50.

In producing the dye-sensitized solar cell of the present invention, it is desirable to store the above-mentioned composition into a case and to carry out sealing, or to carry out the resin sealing of the whole composition.

When the dye sensitized-solar cell of the present invention is irradiated with a solar light or with an electromagnetic wave equivalent to a solar light, the dye adsorbed to the metal oxide semiconductor layer 20 will absorb the irradiated solar light or the electromagnetic wave and will be excited. The electron generated by excitation moves to the metallic current collecting layer 11 and the transparent conductive layer 10 through the metal oxide semiconductor layer 20 and the metal oxide interlayer 60, subsequently the electron moves to the conductive layer 40 of the counter electrode via an external circuit, and it reduces the redox electrolyte of the charge transfer layer 30.

On the other hand, although the dye from which the electron has been moved will be changed to an oxidized form, the dye will return to the original state by being provided with an electron via the redox electrolyte of the charge transfer layer 30 from the counter electrode. At the same time, the redox electrolyte of the charge transfer layer 30 will be oxidized, and it returns again to the state which can be reduced by the electron provided from the counter electrode. Thus, an electron flows and the dye sensitized-solar cell of the present invention can be constituted.

### <Metal Oxide Interlayer>

The dye-sensitized solar cell of the present invention contains a metal oxide interlayer composed ofmetal oxide particles between the conductive base and the metal oxide semiconductor layer.

As a metal oxide which constitutes the metal oxide interlayer, it can be used the same metal oxide used for the metal oxide semiconductor layer which will be described later. Among them, in order to decrease the reverse electric current during irradiation of light and to increase the forward electric current to obtain high photoelectric conversion efficiency, it is preferable to use the metal oxide having the conduction band which has the same or lower level as the lowest conduction band level of the metal oxide used for the metal oxide semiconductor layer.

When the metal oxides which constitute a metal oxide semiconductor layer are titanium oxide and zinc oxide, as a metal oxide used for a metal oxide interlayer, zirconium oxide, strontium titanate, niobium oxide, and zinc oxide are preferable, and strontium titanate and niobium oxide are more preferable.

As a thickness of a metal oxide interlayer, it is preferable that it is from 1 nm to 500 nm, and it is more preferable that it is from 5 nm to 200 nm. The porous ratio of the metal oxide interlayer is preferably smaller than the porous ratio of the metal oxide semiconductor layer, specifically, it is preferable to be 20% or less, and it is more preferable to be 10% or less. When the porous ratio of a metal oxide interlayer becomes small, not only migration of an electronic in reverse direction is difficult to occur, but adhesion to the conductive base and durability will be also improved. Moreover, the metal oxide interlayer may be composed of laminated constitution of two or more layers, and it is possible to control arbitrarily the composition of the metal oxide particles, the thickness and the porous ratio.

Here, the porous ratio indicates the porosity which exhibits penetration in the thickness direction of a dielectric substance, and it can be measured using a commercially available apparatus such as a mercury porosimeter (Porerizer 9220 type made by Shimazu Co., Ltd.).

There is no restriction in particular as a production method for a metal oxide interlayer. Examples of the production method include various thin film forming methods such as: a vacuum deposition method, an ion sputtering process, a cast method, a coating method, a spin coat method, a spray method, an aerosol deposition method (AD method), a dip coating, an electrolytic polymerization method, an optical electrolytic polymerization method and a pressurizing press method.

Among them, a vacuum deposition method and an ion sputtering process can be performed under the well known condition using a commercially available vacuum evaporation apparatus and sputtering system. With respect to a coating method, it can be carried out according to the coating method of the semiconductor particles for the metal oxide semiconductor layer which will be described later. When a transparent base material is not a glass plate but a resin film, the method, such as a pressurizing press method which does not need an elevated-temperature heating step, can be applied preferably.

### <Conductive Base>

In the dye-sensitized solar cell of the present invention, it has a metallic current collecting layer composed of metallic thin wires and a transparent conductivity layer containing a conductive polymer on a transparent base as a conductive base material.

### (Metallic Current Collecting Layer)

There is no limitation in particular in the form of a metallic current collecting layer which is composed of metallic thin wires, and it can be formed in a net form, a stripe shape, or an arbitral pattern. There is no limitation in particular in the material of metallic thin wires, and it can be used, by choosing arbitrarily, a metal, such as gold, silver, copper, platinum, aluminium, nickel, and tungsten, or an alloy containing two or more kinds of these. From the viewpoints of conductivity and the preparation of thin wires, using silver is one of the preferable embodiments.

There is no limitation in particular in the line width of a metallic thin wire and an aperture ratio of a metallic current collecting layer. They can be controlled arbitrary and applied. When the line width becomes small, the conductivity will be decreased, but an aperture ratio becomes high. As a result, the light transmittance as a conductive base becomes high. On the other hand, when the line width becomes large, the conductivity will be increased, but an aperture ratio becomes low. As a result, the light transmittance as a conductive base becomes low.

When these viewpoints are taken into consideration, the line width of a metallic thin wire is specifically preferable to be from 5 μm to 20 μm, and it is more preferable to be from 5 μm to 10 μm. Measurement of the line width of a metallic thin wire can be performed using a microscope with a distance measuring function.

An aperture ratio of metallic current collecting layer is specifically preferable to be from 93% to 98%, and it is more desirable to be from 95% to 98%. Here, an aperture ratio indicates a ratio of the area deducted the area occupied by the metal to the whole conductive base area irradiated with lights. It is represented by the formula:

[(Aperture ratio)={(whole area)−(area occupied by metal thin wires)}/(whole are)×100].

The aperture ratio can be obtained by analyzing the picture image taken with a microscope, and by measuring the aperture area.

Moreover, the interval of metal thin wires is also a factor which influences an aperture ratio, and it is possible to determine it arbitrarily. Usually, it can be set in the range of 10 μm to 500 μm. Further, although there is also no limitation in particular in the height of a metallic thin wire, when the whole surface smoothness is taken into consideration as a conductive base, it is preferable to be from 1 μm to 10 μm.

There is no limitation in particular in the way of forming a metal thin wire, and the following methods can be applied arbitrarily. Examples of the methods include: a vacuum deposition method, a sputtering process, an ion plating method, a CVD method, a plasma CVD method, a coating method, an ink-jet method, a screen printing, an aerosol deposition method, and also a silver salt method. Among these methods, it is preferable to apply an ink-jet method or a silver salt method.

More specifically, the following method can be used. A photoresist is applied on a transparent base, then a pattern light exposure is performed through a mask, followed by etching to remove the part corresponding to the metal thin wire pattern on the photoresist. Subsequently, after forming the above-mentioned metallic film as a film uniformly by sputtering for example, the photoresist can be removed by the lift-off method and a metal thin wire can be formed. Or it may be used the following method. After forming a metallic film as a film uniformly on the above-mentioned base, then a photoresist is applied to this metallic film and canying out a pattern light exposure through a mask. Subsequently, the positive part of a resist is dissolved, and the metallic film appeared is removed by etching to form a metal thin wire.

The following method can be cited as the coating method. Metal particles which become metallic thin wires and glass particles which become a binder are blended to form a paste. Then it is coated so as to form a prescribed pattern by the method such as a coating method, an ink-jet method and a screen printing. Then the coated film is heated and it is calcined to melt the metallic particles. It is preferable to control the calcined temperature below 600° C., for example, when a transparent base is a glass.

The shapes of the metallic particles used for the methods such as a coating method, an ink-jet method and a screen printing are not limited in particular. It is possible to use the particles of various forms. It is preferable to use nanowire or spherical particles from the viewpoint of increasing an effective conductive contact, and it is more desirable to use nanowires. As for wire length, although the size of nanowire does not have limitation in particular, nanowire having a diameter of 10 nm to 100 nm is preferable, and nanowire having a length of 10 μm to 100 μm is preferable.

It is possible to apply various well-known methods as an ink-jet method. Especially, the electrostatic ink-jet method can continuously print the liquid of high viscosity with high precision, and it is preferably used for forming a metal thin wire. For forming a metal thin wire, it is preferable to use a liquid ejecting apparatus provided with: a liquid discharge head having nozzles of an internal diameter from 0.5 to 30 μm to discharge the charged liquid; a supply means to provide a solution in the above-mentioned nozzles; and a discharge voltage impression means to impress discharge voltage to the solution in the above-mentioned nozzles. According to this method, there is no overweight at an intersection of metal thin wires, and thinning of lines is possible.

As specific methods for forming a metal thin wire using such an electrostatic ink-jet method, the following methods can be cited, for example: the method of forming a metal thin wire by electroless deposition method, after applying plating catalyst ink to form a predetermined pattern; the method of applying the ink containing metal particles, or the ink containing metal ions or metal complex ions with a reducing agent to form a predetermined pattern; and the method of applying the ink containing metal ions or metal complex ions, and the ink containing a reducing agent thorough different nozzles to form a predetermined pattern.

Especially, the following methods are more preferable since they do not require an additional process such as plating process: the method of coating the ink containing metal particles, or the ink containing metal ions or a metal complex ion with a reducing agent to form a predetermined pattern; and the method of coating the ink containing metal ions or metal complex ions, and the ink containing a reducing agent thorough different nozzles to form a predetermined pattern. Furthermore, if it is the method ofusing the ink containing metal ions or a metal complex ion with a reducing agent, or applying the ink containing metal ions or metal complex ions, and the ink containing a reducing agent thorough different nozzles to form a predetermined pattern, they can be used most preferably for the application of high smoothness requirement, since it is hard to produce irregularity on a surface of the metal thin wires compared with the method using the ink containing metal particles.

The viscosity of the ink used in the electrostatic ink-jet method is preferably 30 mPa·s or more, and more preferably, it is 100 mPa·s or more.

Next, a silver salt method will be described.

A silver salt method is the following method: preparing a layer containing a silver halide grain on a transparent base, and forming the metallic silver portion having a required pattern by light exposure with a predetermined pattern followed by developing treatment, and then further forming a silver thin line by carrying out a physical development process. By the silver salt method, it is possible to avoid the aperture ratio decrease by intersection point overweight which may become a problem by the printing method. It is possible to form a precise silver line, and applying a silver salt method is one of the preferable embodiments.

When the layer containing the above-mentioned silver halide grain is formed, a binder is contained in the silver halide emulsion. As an amount of the binder in the layer containing a silver halide grain, it is preferable to be from 0.05 g/m² to 0.25 g/m². As a ratio of Ag/binder in the layer containing a silver halide grain, it is preferable to be from 0.3 to 0.8 measured as a volume ratio. As for the above-mentioned silver halide grain, it is preferable that it is a silver chlorobromide particle. The silver chloride content is preferably from 55 mol % to 95 mol %, and the silver bromide content is preferably from 5 mol % to 45 mol %.

The details of light exposure, photographic processing and a physical development process can be referred to the methods described in JP-A No. 2006-352073.

After forming a metallic thin wire on a transparent base by the various methods described above, it is possible to perform plating treatment on the metallic thin wire, or to prepare a corrosion prevention layer for preventing the attack by an electrolyte to the metallic thin wire if needed. When performing plating treatment, it can be carried out under the arbitrary conditions by using an electrolytic plating method or an electroless deposition method. When preparing a corrosion prevention layer, it is possible to apply metal such as titanium, nickel, and aluminum, or these alloys, and it is also possible to apply an amorphous or a crystalline insulating layer as a corrosion prevention layer.

### (Transparent Conductive Layer)

Next, a transparent conductive layer provided on the transparent base of the present invention will be described.

The transparent conductive layer of the present invention contains a conductive polymer. By containing a conductive polymer, it is possible to make a flat electrode with few losses even if a large area is produced. In particular, when a resin film is used as a transparent base, it is possible to make a conductive base which is strong against bending compared with inorganic system conductive films such as ITO.

It is possible to use the well-known polymers having a various structure as a conductive polymer contained in a transparent conductive layer. The following can be cited as examples of a conductive polymer: a polypyrrole system, a polyindole system, a polycarbazole system, a polythiophene system, a polyaniline system, a polyacetylene system, a polyfiran system, a polyparaphenylenevinylene system, a polyazulene system, a polyparaphenylene system, a polyparaphenylenesulfide system, a polyisothianaphthene system, a polythiazyl system and a polyacene system. Among them, a polyethylenedioxythiophene system and a polyaniline system are preferable from the viewpoints of conductivity and transparency.

In the present invention, in order to further improve the conductivity of the above-mentioned conductive polymer, it is preferable to perform a doping treatment to a conductive polymer. As a dopant which can be used for a doping treatment, at least one selected from the following group is cited: a sulfonic acid having a hydrocarbon group of 6 to 30 carbon atoms (it is also called as “a long chain sulfonic acid”) or its polymer (for example, polystyrene sulfonic acid), a halogen compound, a Lewis acid, a proton acid, a transition metal halide, a transition metal compound, an alkali metal, an alkaline earth metal, MClO₄ (M=Li⁺, Na⁺), R₄N⁺(R═CH₃, C₄H₉, C₅H₁₁), or R₄P⁺ (R═CH₃, C₄H₉, C₅H₁₁. Among them, the above-mentioned long chain sulfonic acid is preferable.

Examples of a long chain sulfonic acid include: dinonylnaphthalenedisulfonic acid, dinonylnaphthalenesulfonic acid and dodecylbenzenesulfonic acid. Examples of a halogen compound include: Cl₂, Br₂, I₂, ICl₃, IBr and IF₅. Examples of a Lewis acid include: PF₅, AsF₅, SbF₅, BF₃, BCl₃, BBr₃, SO₃ and GaCl₃. Examples of a proton acid include: HF, HCl, HNO₃, H₂SO₄, HBF₄, HClO₄, FSO₃H, ClSO₃H and CF₃SO₃H. Examples of a transition metal halide include: NbF₅, TaF₅, MoF₅, WF₅, RuF₅, BiF₅, TiCl₄, ZrCl₄, MoCl₅, MoCl₃, WCl₅, FeCl₃, TeCl₄, SnCl₄, SeCl₄, FeBr₃ and SnI₅. Examples of a transition metal compound include: AgClO₄, AgBF₄, La(NO₃)₃ and Sm(NO₃)₃. Examples of an alkali metal include: Li, Na, K, Rb and Cs. Examples of an alkaline earth metal include: Be, Mg, Ca, Sc and Ba.

The dopant to a conductive polymer may be introduced into a fullerene such as hydrogenated fullerene, hydroxylated fullerene and sulfonated fullerene. The above-mentioned dopant is preferably contained in an amount of 0.01 weight parts or more to 100 weight parts of the conductive polymer, and more desirably it is contained in an amount of 0.5 weight parts or more.

In the present invention, a water-soluble organic compound may be contained in a transparent conductive layer other than a conductive polymer. There is no limitation in particular in the water-soluble organic compound which can be used for the present invention. It is possible to choose suitably from the known compounds, for example, an oxygen containing compound is cited suitably.

As long as oxygen is contained in an oxygen containing compound, there is no limitation in particular, for example, a hydroxyl group containing compound, a carbonyl group containing compound, an ether group containing compound and a sulfoxide group containing compound are cited. Here, as a hydroxyl group containing compound, for example, ethylene glycol, diethylene glycol, propylene glycol, trimethylene glycol and 1,4-butanediol, glycerol are cited. As a carbonyl group containing compound, for example, isophorone, propylene carbonate, cyclohexanone and gamma-butyrolactone are cited. As an ether group containing compound, for example, diethylene glycol monoethyl ether is cited. As a sulfoxide group containing compound, for example, dimethyl sulfoxide is cited. Among them, it is especially preferable to use at least one selected from the group of dimethyl sulfoxide, ethylene glycol and diethylene glycol. These compounds may be used alone and they may be used two or more sorts together.

The content of a water-soluble organic compound to 100 weight parts of a conductive polymer is preferably 0.001 weight parts or more, it is more preferable to be from 0.01 to 50 weight parts, and it is especially preferable to be from 0.01 to 10 weight parts.

There is no limitation in particular in the method for forming a transparent conductive layer. It is possible to apply arbitrarily the well-known methods to form a conductive polymer layer. It is preferable to prepare the coating solution containing a conductive polymer and a dopant, and then, applying this on a transparent base or on a metallic current collecting layer.

As a conductive base of the present invention, there will be no limitation in particular in the order of the composition as long as it contains a transparent base having thereon a metallic current collecting layer composed of metallic thin wires, and a transparent conductive layer containing a conductive polymer. A transparent conductive layer may be formed after initially forming a metallic current collecting layer on a transparent base. Or, a metallic current collecting layer may be formed after initially forming a transparent conductive layer.

However, the embodiment which forms a transparent conductivity layer after previously forming a metallic current collecting layer on a transparent base is more preferable from the viewpoint of preventing the corrosion of a metallic thin wire by the attack of the electrolyte, and also from the viewpoint of controlling the surface smoothness as the whole conductive base. Furthermore, in this case, it is most preferable that the uppermost surface of the conductive base becomes smooth and the surface of the metallic thin wire will not contact an electrolyte by the fact that a transparent conductivity layer covers the opening of the metallic current collecting layer and the upper portion of the metallic thin wire.

Here, the smoothness in the present invention means an arithmetic mean roughness Ra specifically specified by HS B-0601 is 1 μm or less. Measurement of the average roughness can be done using a non-contact three-dimensional minute surface shape measuring system such as, for example, RSTPLUS (made by WYCO Ltd.).

The thickness of a transparent conductivity layer is preferably from 0.01 μm to 5 μm, and it is more preferably from 0.05 μm to 2.0 μm. When the transparent conductive layer covers the upper portion of the metallic current collecting layer, it is preferable that the upper portion of the metallic thin wire will have this thickness.

The conductive base used in the dye sensitized solar cell of the present invention has an embodiment which uses both a metallic current collecting layer and a transparent conductive film, and it can control a surface resistance value to be low. A surface resistance value is specifically preferable to be below 10 Ω/□, it is more preferable to be below 5 Ω/□, and it is still more preferable to be below 1 Ω□. Surface resistance can be measured, for example, based on JIS K6911 and ASTM D257, and it can be measured using a commercially available surface resistance meter.

### <Transparent Base>

A glass plate and a resin film can be used as a transparent base used for a conductive base in the dye-sensitized solar cell of the present invention.

Specific examples of a resin film include: polyester such as polyethylene terephthalate (PET) and polyethylene naphthalate; polyolefin such as polyethylene (PE), polypropylene (PP), polystyrene and cyclic olefin resin; vinyl resin such as polyvinylchloride and polyvinylidene chloride; polyether ether ketone (PEEK), polysulfone (PSF), polyethersulfone (PES), polycarbonate (PC), polyamide, polyimide, acrylic resin and triacetyl cellulose (TAC).

Among them, from the viewpoints of transparency, heat resistivity, the ease of handling and cost, it is preferable that they are a biaxial stretching polyethylene terephthalate film, an acrylic resin film and a triacetyl cellulose film. Most preferable is a biaxial stretching polyethylene terephthalate film.

### <Metal Oxide Semiconductor Layer>

The metal oxide semiconductor layer concerning the present invention will be described.

As a metal oxide which constitutes the metal oxide semiconductor layer concerning the present invention, as long as it is a semiconductor which can receive the electron generated by light exposure to the dye adsorbed to the semiconductor and can transmit this electron to a conductive base, there is no limitation in particular. Various metal oxides used for a well-known dye sensitized solar cell can be used.

Specific examples of a metal oxide include: various metal oxide semiconductors such as titanium oxide, zirconium oxide, zinc oxide, vanadium oxide, niobium oxide, tantalum oxide and tungsten oxide; various composite metal oxide semiconductors such as strontium titanate, calcium titanate, magnesium titanate, barium titanate, potassium niobate and strontium tantalate; transition metal oxides such as magnesium oxide, strontium oxide, aluminium oxide, cobalt oxide, nickel oxide and manganese oxide; metal oxides such as cerium oxide, gadolinium oxide, samarium oxide and a lanthanoid oxide such as ytterbium oxide; and inorganic insulators represented by silica, such as a natural silica compound and a synthetic silica compound.

These compounds may be used in combination thereof. Furthermore, it is possible to make a metallic oxide particle into a core-shell structure, or to dope a different metallic element. It is possible to apply a metal oxide having an arbitral structure and composition.

The average grain diameter of metallic oxide particles is preferably from 10 nm to 300 nm, and it is more preferably from 10 nm to 100 nm. The forms of a metal oxide are not limited in particular, either, and they may be a globular, a needlelike, or an amorphous crystal.

There is no limitation in particular in the formation method of a metal oxide particle. It can be fomied with: various liquid phase methods such as a hydrothermal reaction method, a sol-gel method/a gel-sol method, a colloid-chemical synthetic method, a coating thermal decomposition method and an evaporation thermal decomposition method; and various gaseous phase methods such as a chemical vapor deposition method.

Next, the production methods of the metal oxide semiconductor layer concerning the present invention will be described.

It is possible to apply the well-known methods for the production method of the metal oxide semiconductor layer in the dye sensitized solar cell of the present invention, and the following methods can be applied:
(1) The method having a step of coating a suspension containing metal oxide particles or its precursor on a conductive base, followed by performing drying and calcination to form a semiconductor layer;
(2) The migration elecirodeposition method having a step of immersing a conductive base into a colloidal solution so that a metal oxide semiconductor particle is deposited on the conductive base by an electrophoresis;
(3) The method having a step of coating a colloid solution or a colloid dispersion after mixing with a foaming agent, followed by sintering to make a porous material; and
(4) The method having a step of coating a mixture of polymer micro beads, followed by subjecting to a heat-treatment or a chemical treatment to remove these polymer micro beads resulting in voids to make a porous material.

In the above-mentioned production methods, it is possible to apply well-known methods for the coating method, there can be cited, for example, a screen printing, an ink-jet method, a roll coat method, a doctor blade method, a spin coat method and a spray coating method.

Especially, in the case of the above-described method (1), the particle diameter of the metal oxide particles in the suspension is preferably to be minute, and it is preferable to exist as a primary particle. The suspension containing metal oxide particles is prepared by dispersing metal oxide particles in a solvent. As a solvent, there is no limitation in particular as long as the metal oxide particles can be dispersed. It can be cited water, an organic solvent and the mixed liquid of water and an organic solvent As an organic solvent, the followings can be used: alcohols such as methanol and ethanol; ketones such as methyl ethyl ketone, acetone and acetylacetone hydrocarbons; and hydrocarbons such as hexane and cyclohexane. Into the suspension, a surfactant and a viscosity modifier (a polyhydric alcohol such as polyethylene glycols) can be added if needed. As for the range of the concentration of the metal oxide particles in the solvent, 0.1 to 70 weight % is preferable, and 0.1 to 30 weight % is more preferable.

After coating the suspension containing the core particles of the metal oxide obtained by the above-described method on a conductive base and performing drying, it is calcined in the air or in an inert gas, and a metal oxide semiconductor layer is formed on the conductive base. The semiconductor layer obtained by coating and drying the suspension on the conductive base is composed of an aggregate of metal oxide particles, and the particle diameter of the particles is equivalent to the primary particle diameter of the used metal oxide particles. The metal oxide semiconductor layer formed on the conductive base has a weak bonding strength with the conductive base, the bonding strength between particles is also weak, and mechanical strength is weak. Therefore, it is preferable to carry out calcination treatment to this metal oxide particle aggregate membrane so as to raise mechanical strength, and to anchor it strongly to the base.

In the present invention, although this metal oxide semiconductor layer may have any kinds of structure, it is preferable that it is a porous structure membrane (having a void structure or it is also called a porous layer). As for the porous ratio of the metal oxide semiconductor layer, it is preferable to be from 0.1 to 20 volume %, and it is more preferable to be from 5 to 20 volume %. Here, the porous ratio of the metal oxide semiconductor layer indicates the porosity which exhibits penetration in the thickness direction of a dielectric substance, and it can be measured using a commercially available apparatus such as a mercury porosimeter (Porerizer 9220 type made by Shimazu Co., Ltd.). As for the thickness of the metal oxide semiconductor layer, it is preferable to be at least 10 nm or more, and it is more preferable to be from 100 to 10000 nm.

At the time of calcination treatment, from the viewpoints of appropriately adjusting the real surface area of the semiconductor layer and to obtain the semiconductor layer having the above-mentioned porous ratio, the calcination temperature is preferably lower than 1,000° C., and it is more preferably in the range of 200 to 800° C.

In the metal oxide semiconductor layer concerning the present invention, after forming a metal oxide semiconductor layer on a metal oxide interlayer as described above, it is possible to perform surface treatment using a metal oxide on the metal oxide semiconductor layer for the purpose of raising electron conductivity, if needed. As the composition of this surface treatment material, it is preferable to use the same kinds of composition as the metal oxide which forms the metal oxide semiconductor layer from the viewpoint of an electron conductivity between the metal oxide particles.

There are the following methods for performing this surface treatment: after forming a metal oxide semiconductor layer on a conductive base, the precursor of the metal oxide used as a surface treatment material is coated to this semiconductor layer, or immersing this semiconductor layer into a precursor solution, and further carrying out calcination treatment if needed to perform a surface treatment using the metal oxides.

Specifically, the surface treatment can be performed with an electrochemical process using an aqueous solution of titanium tetrachloride or titanium alkoxide which is a precursor of titanium oxide; or the surface treatment can be performed using a precursor of an alkali metal titanate or an alkaline earth metal titanate. Although the calcination temperature or the calcination time in this case is not limited in particular and it can be controlled arbitrarily, it is preferable to be 200° C. or less.

### <Dye>

The dye used for the present invention will be described.

In the present invention, as a dye which is made to adsorb to the surface of the above-mentioned metal oxide semiconductor layer, preferable is a dye which has an absorption in the range of visible light region or infrared light region, and has a minimum vacant level higher than the conduction band of the metal oxide semiconductor. It is possible to use well-known various dyes.

Examples of the dye include: an azo system dye, a quinone system dye, a quinone imine system dye, a quinacridone system dye, a squarylium system dye, a cyanine system dye, a cyanidin system dye, a merocyanine system dye, a triphenylmethane system dye, a xanthene system dye, a porphyrin system dye, a perylene system dye, an indigo system dye, a phthalocyanine system dye, a naphthalocyanine system dye, a rhodamine system dye and a rhodanine system dye

In addition, a metal complex dye can be preferably used. In that case, the following metal can be used: Cu, Ni, Fe, Co, V, Sn, Si, Ti, Ge, Cr, Zn, Ru, Mg, Al, Pb, Mn, In, Mo, Y, Zr, Nb, Sb, La, W, Pt, Ta, Ir, Pd, Os, Ga, Tb, Eu, Rb, Bi, Se, As, Sc, Ag, Cd, Hf, Re, Au, Ac, Tc, Te and Rh.

Among the above-described dyes, poly methine dyes, such as a cyanine dye, a merocyanine dye and a squarylium dye, are preferable embodiments. Specifically, the dyes described in each specification of the following documents can be cited: JP-A No. 11-35836, JP-A No. 11-67285, JP-A No. 11-86916, JP-A No. 11-97725, JP-A No. 11-158395, JP-A No. 11-163378, JP-A No. 11-214730, JP-A No. 11-214731, JP-A No. 11-238905, JP-A No. 2004-207224, JP-A No. 2004-319202, European patent No. 892,411 and European patent No. 911,841.

Furthermore, a metal complex dye is also one of the desirable embodiments. Preferable dyes are a metal phthalocyanine dye, a metalloporphyrin dye, and a ruthenium complex dye. Especially preferable dye is a ruthenium complex dye.

As a ruthenium complex dye, the complex pigments disclosed in the following documents can be cited, for example: U.S. Pat. No. 4,927,721, U.S. Pat. No. 4,684,537, U.S. Pat. No. 5,084,365, U.S. Pat. No. 5,350,644, U.S. Pat. No. 5,463,057, U.S. Pat. No. 5,525,440, JP-A No. 7-249790, JP-A No. 504512, WO 98/50393, JP-A No. 2000-26487, JP-A No. 2001-223037, JP-A No. 2001-226607, Japanese patent No. 3430254.

In the present invention, especially a rhodanine system dye is used as a dye which is adsorbed on the surface of a metal oxide. Any structures can be preferably used as long as it is a rhodanine system dye. However, it is especially preferable to use at least one of the compounds represented by the following Formula (1) and the compounds represented by the following Formula (2).

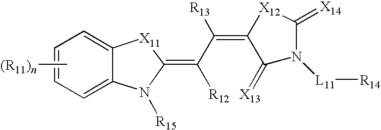

In Formula, R₁₁ represents a substituent, n is an integer of 0 to 4, X₁₁ to X₁₄ each represents an oxygen atom, a sulfur atom or a selenium atom, R₁₂ and R₁₃ each represents a hydrogen atom or a substituent, R₁₄ represents a carboxyl group or a phosphono group, L₁₁ represents a divalent linking group, and R₁₅ represents an alkyl group.

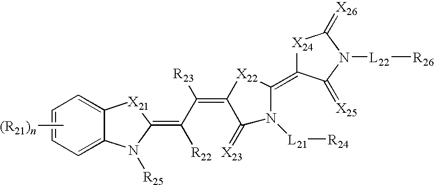

In Formula, R₂₁ represents a substituent, n is an integer of 0 to 4, X₂₁ to X₂₆ each represents an oxygen atom, a sulfur atom or a selenium atom, R₂₂ and R₂₃ each represents a hydrogen atom or a substituent, R₂₄ and R₂₆ represents a carboxyl group or a phosphono group, provided that at least one of R₂₄ and R₂₆ represents a carboxyl group or a phosphono group, L₂₁ and L₂₂ each independently represents a divalent linking group, and R₂₅ represents an alkyl group.

The compound (dye) represented by Formula (1) and the compound (dye) represented by Formula (2) each includes the ion and the salt which are derived from these compounds other than the compounds represented by Formulas themselves. For example, when the compound has a sulfonic acid group (sulfo group) in the molecular structure, the anion formed by dissociation of the sulfonic acid group, and the salt formed by the anion and a counter cation are included.

As such a salt, it may be a salt formed with a metal ion such as a sodium salt, a potassium salt, a magnesium salt and a calcium salt. It may be a salt formed with an organic base such as pyridine, piperidine, triethylamine, aniline, and diazabicycloundecene.

In the case of the compound which has a basic group in the molecule, there are also contained a cation produced by protonation of the compound, and a salt formed with an acid such as a hydrochloride, a sulfate, a acetate, a methylsulfonic acid salt and a p-toluenesulfonic acid salt.

Preferably usable examples of a compound represented by Formula (1) or Formula (2) used for the present invention are shown below.

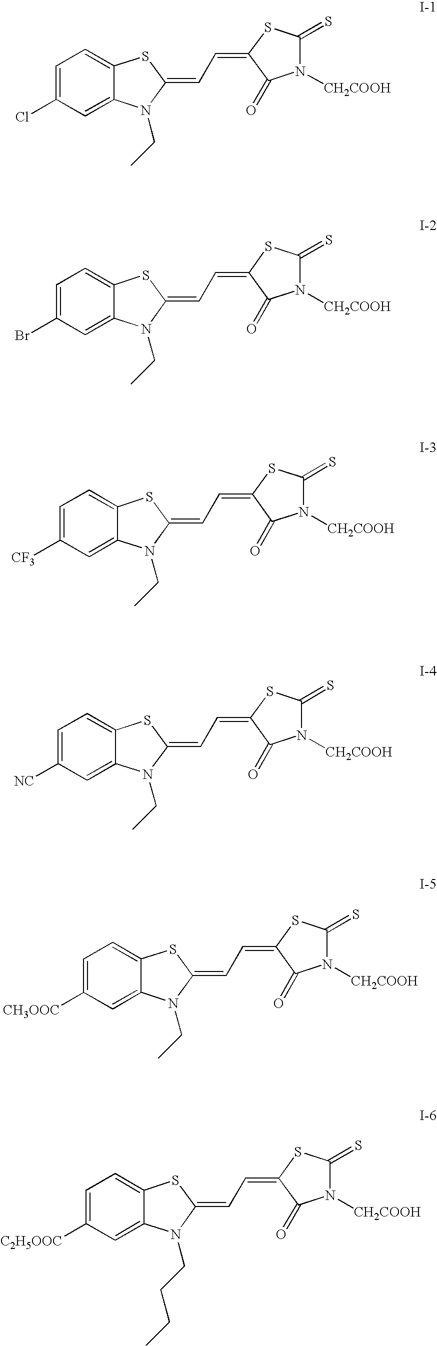

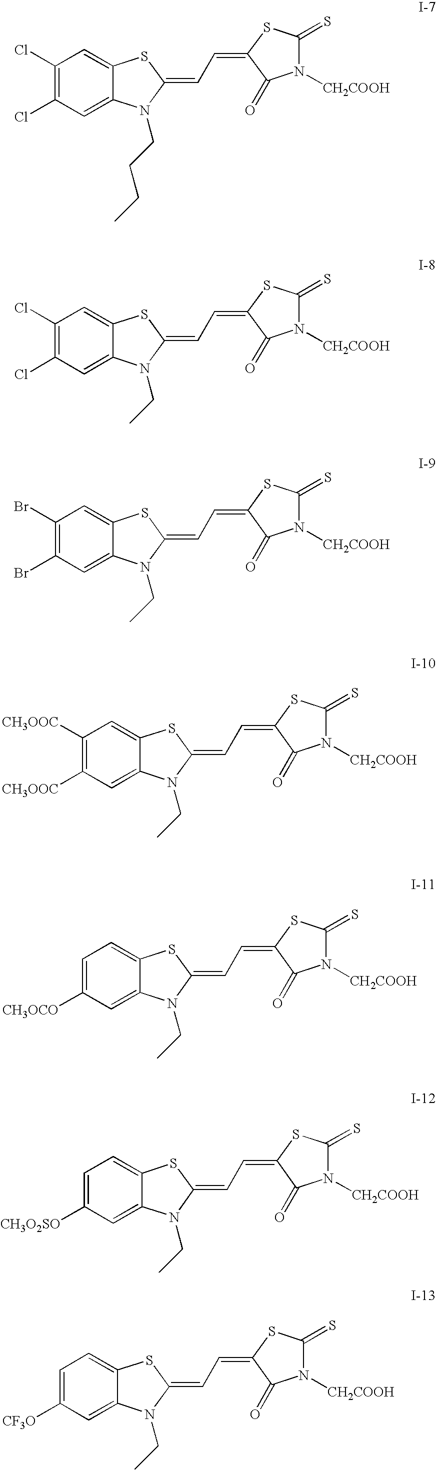

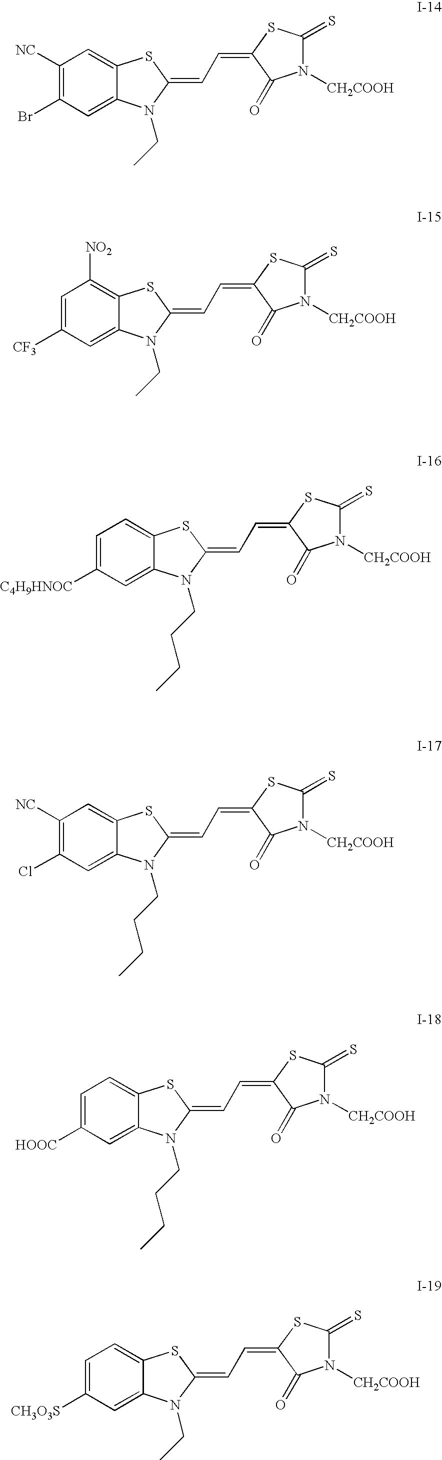

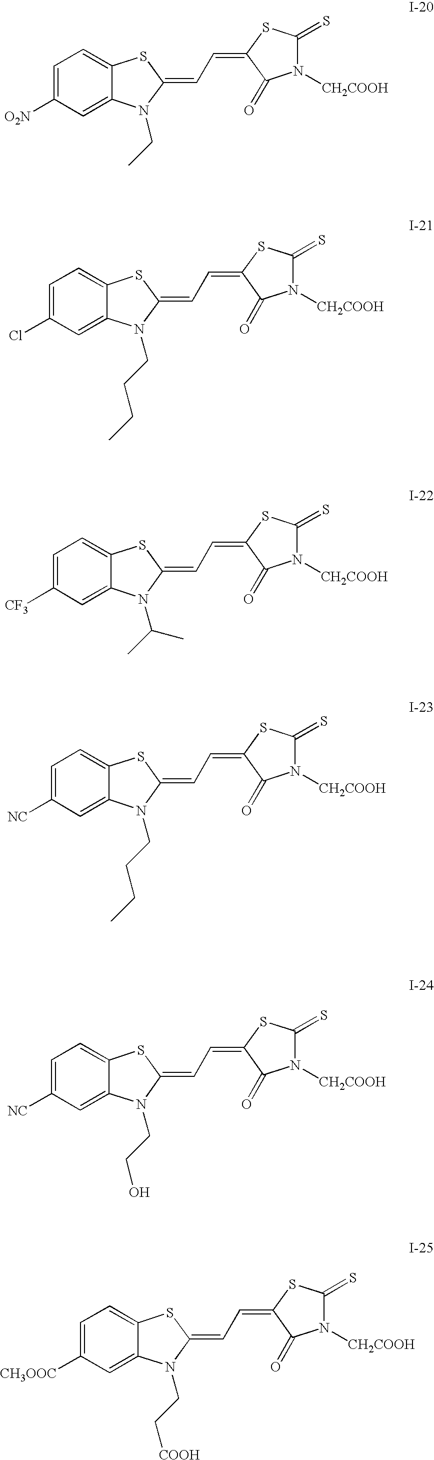

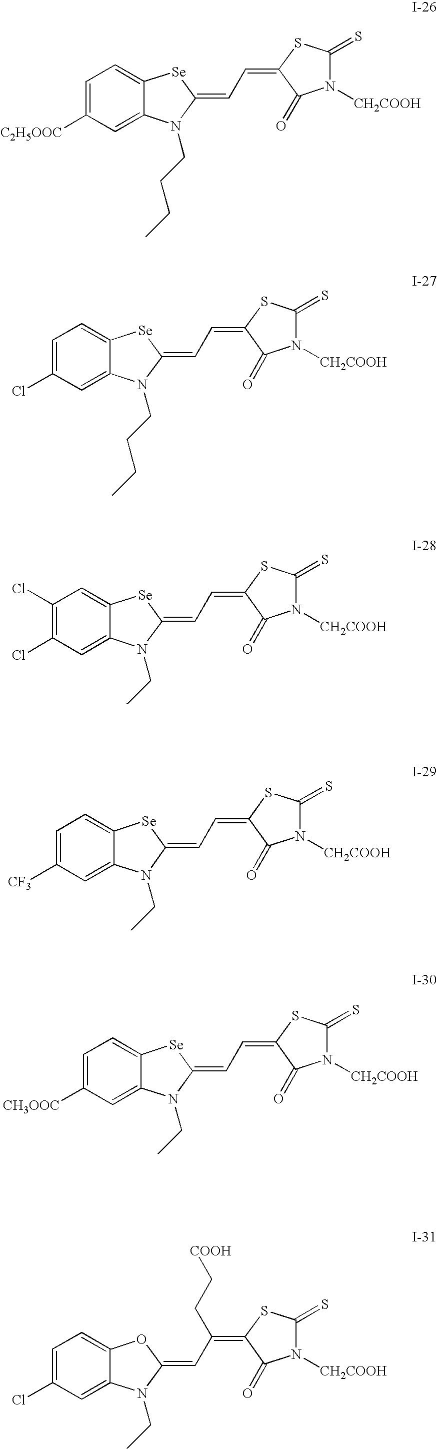

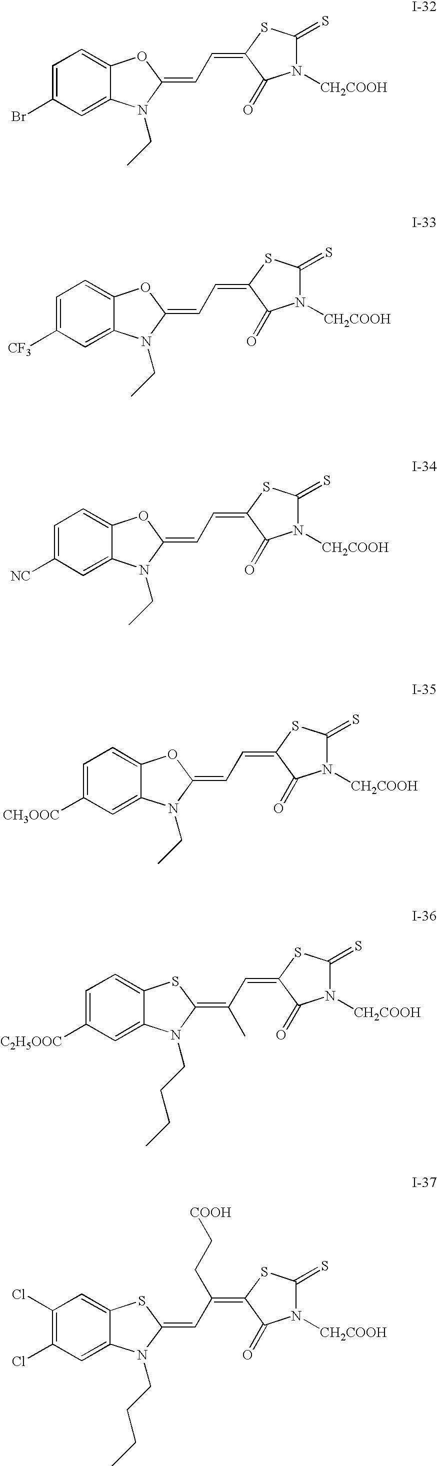

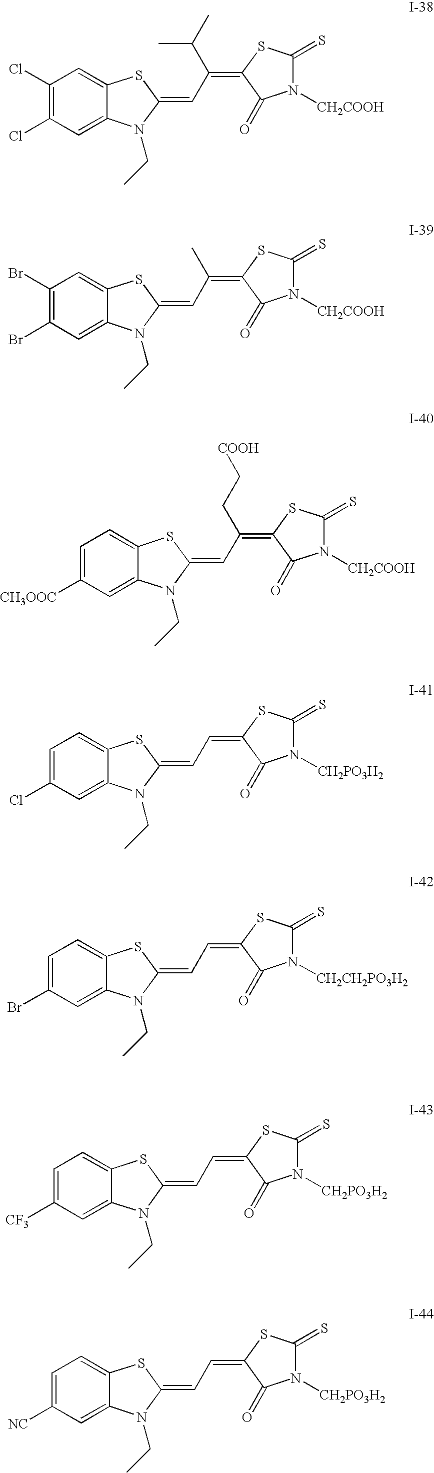

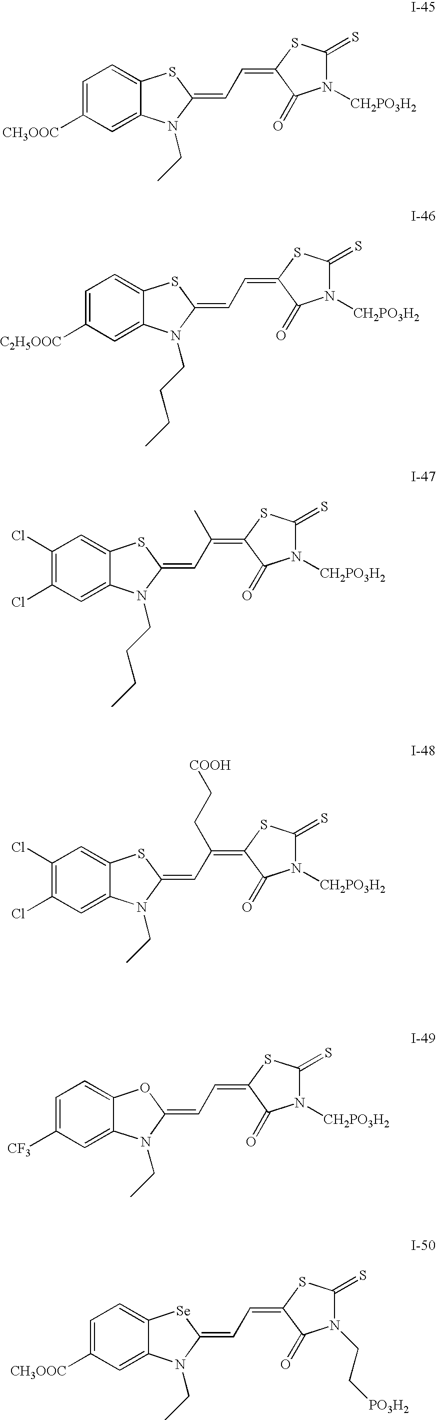

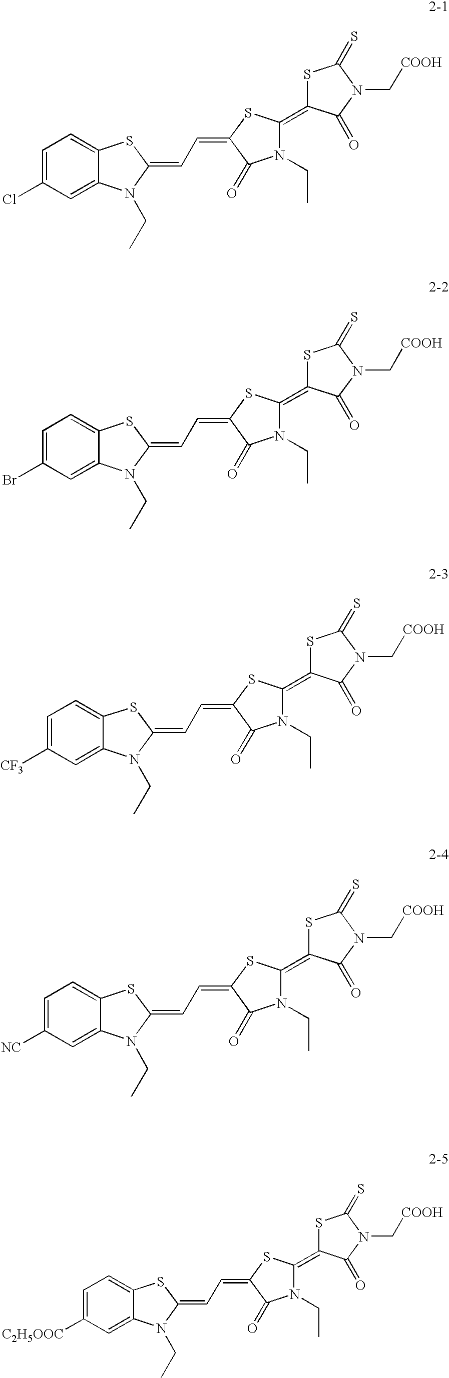

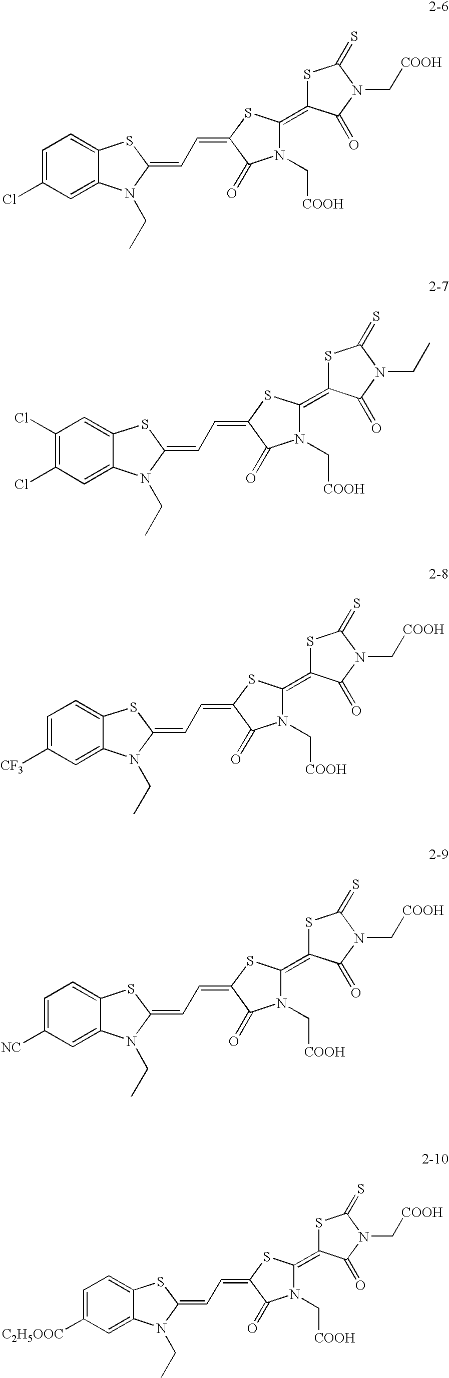

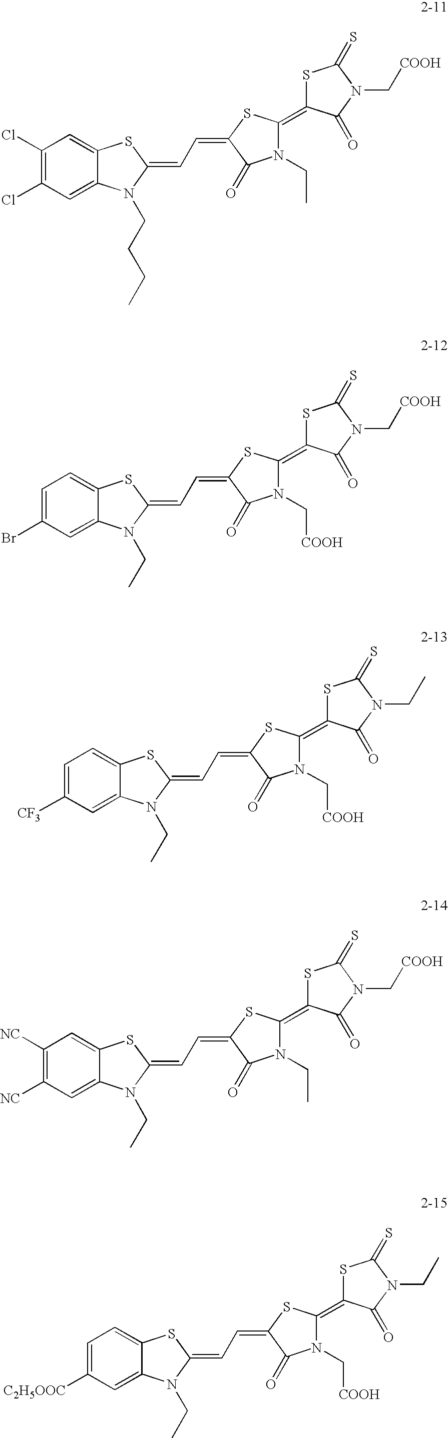

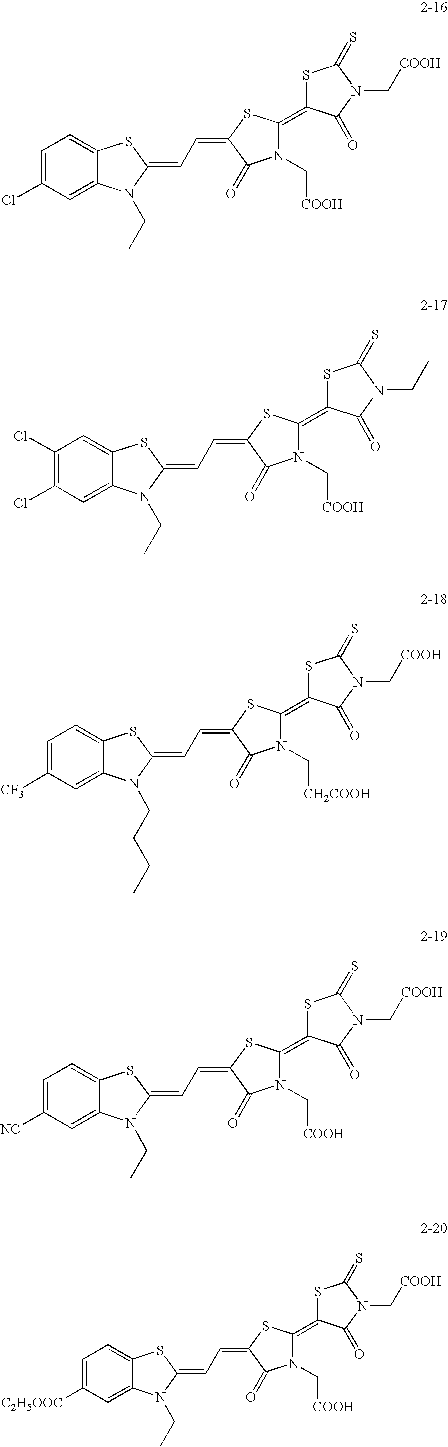

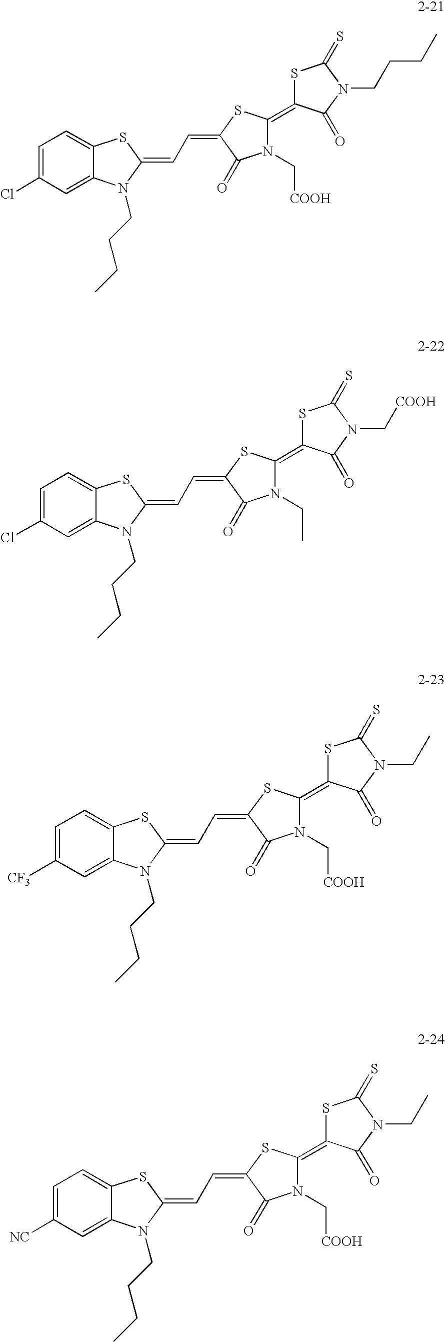

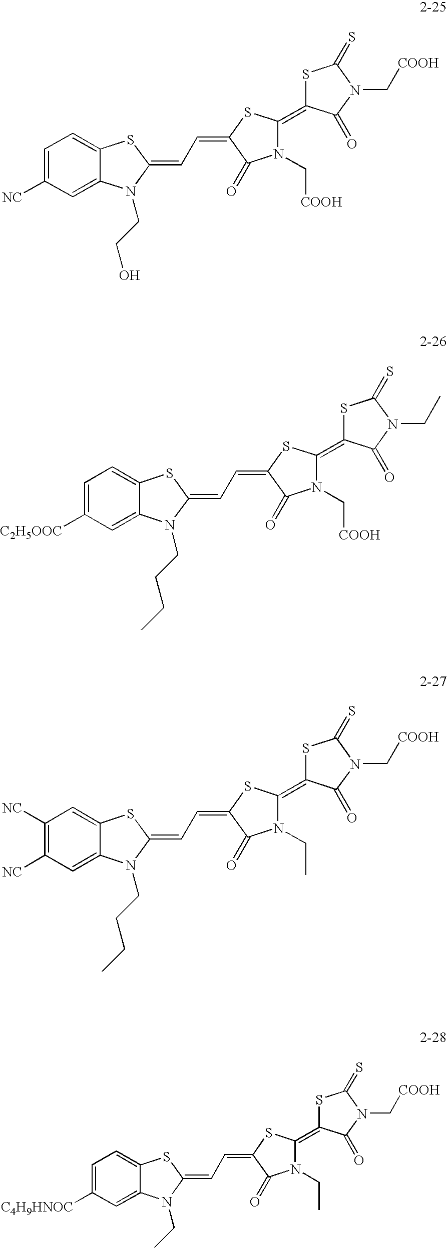

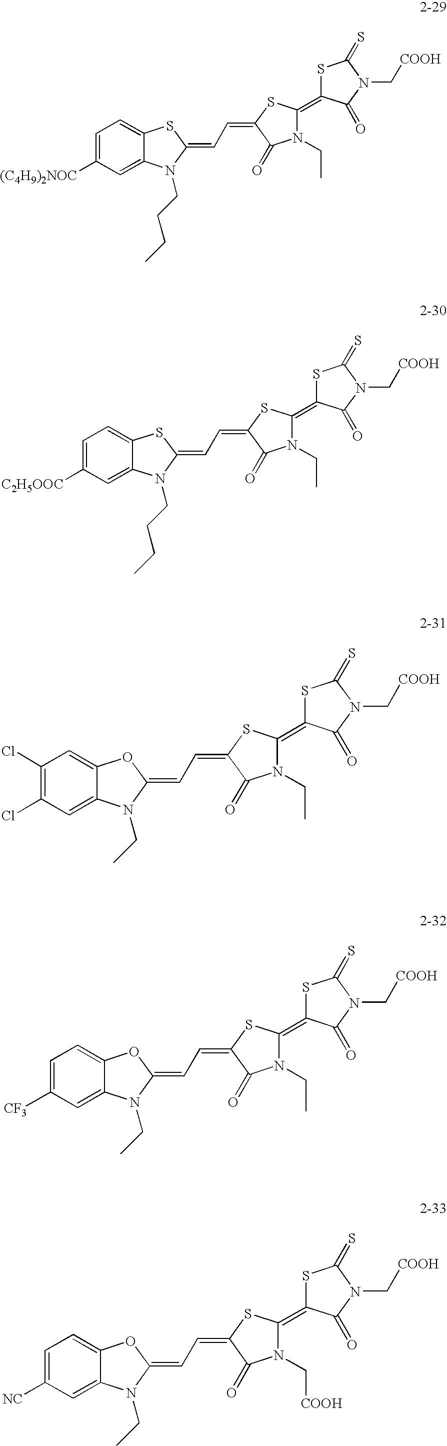

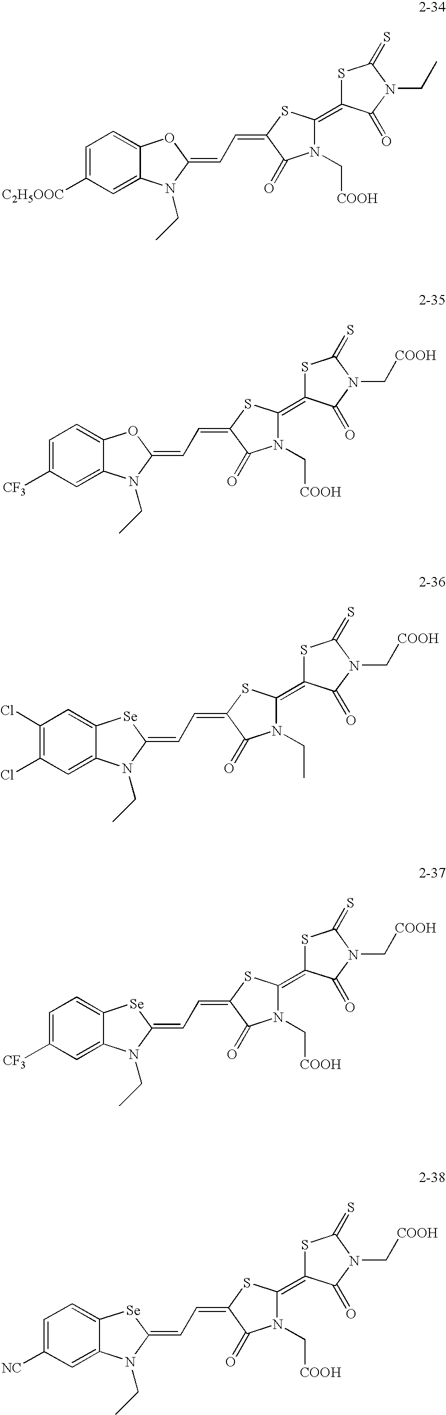

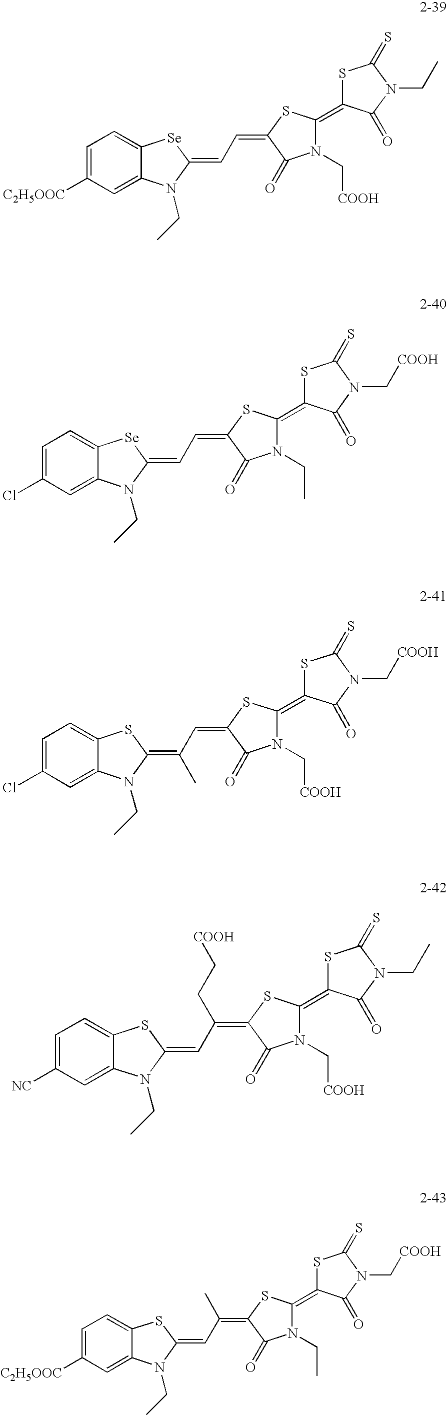

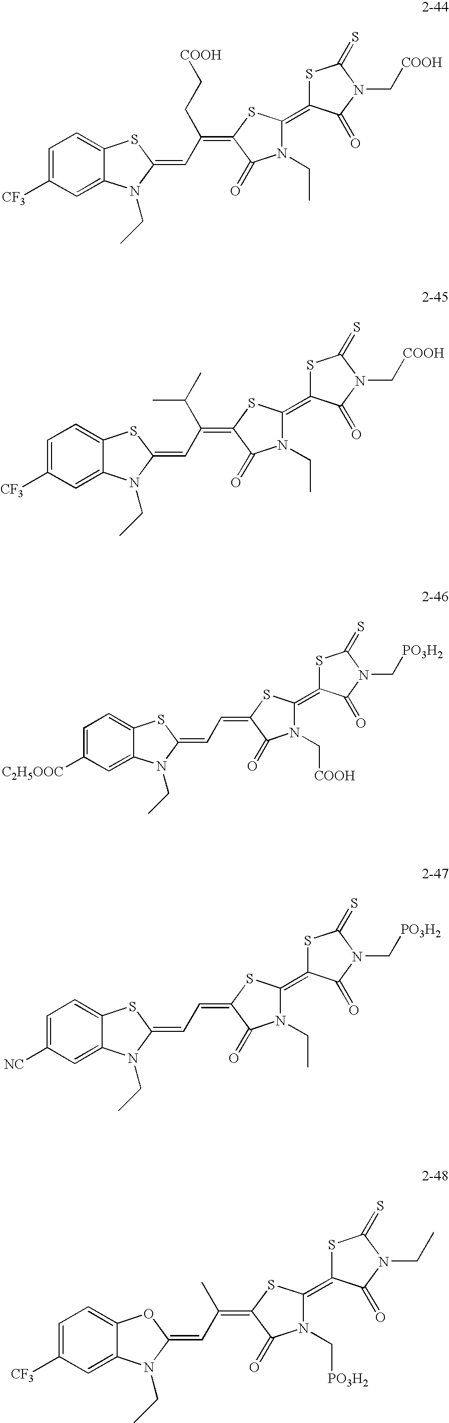

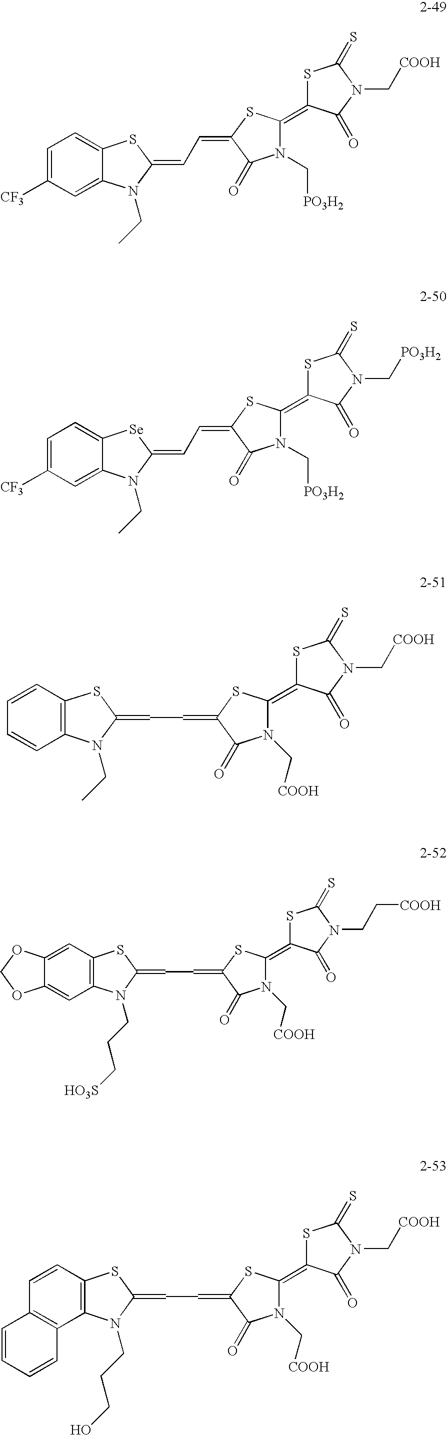

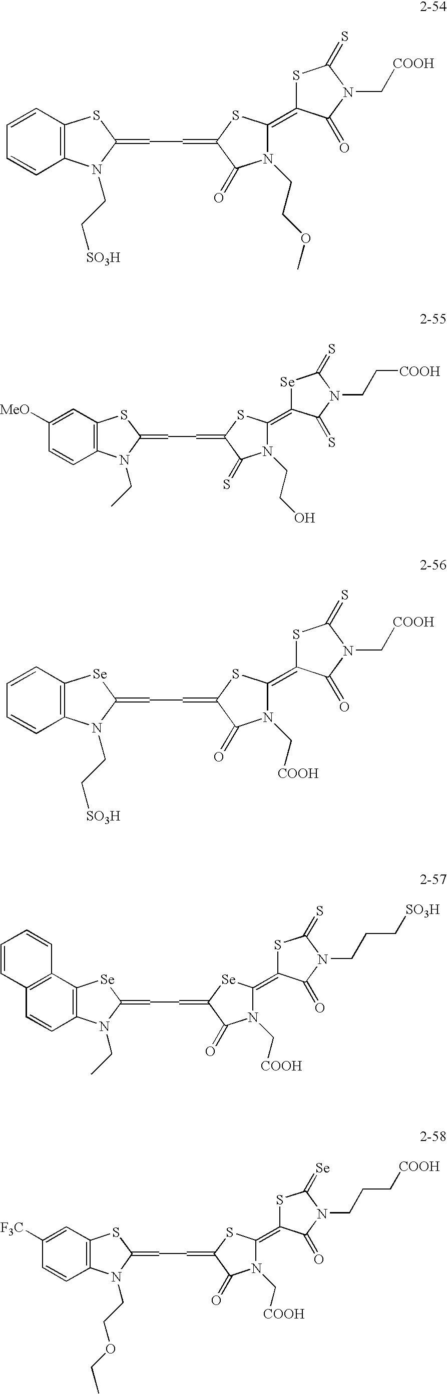

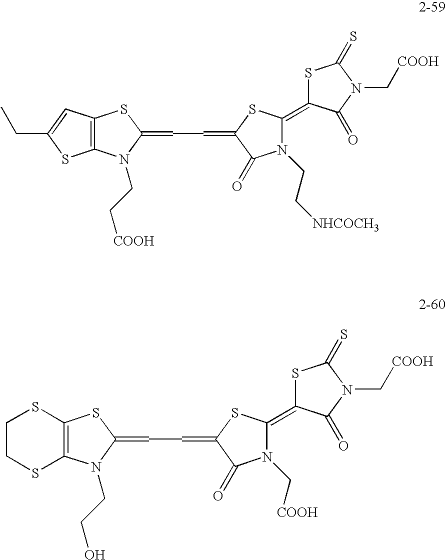

The compound represented by Formula (1) and the compound represented by Formula (2) can be synthesized by referring to the conventionally known methods described in the documents of “Cyanine dyes and related compounds” by F. M. Hamer (published from Interscience Publishers, 1964); U.S. Pat. No. 2,454,629, U.S. Pat. No. 2,493,748, JP-A No. 6-301136 and JP-A No. 2003-203684

It is preferable that these compounds (dyes) exhibit a large absorption coefficient and are stable to a repeated oxidation-reduction reaction.

It is preferable that the above-mentioned compound (dye) is chemically adsorbed on a metal oxide semiconductor. It is preferable that it has a functional group such as a carboxyl group, a sulfonic acid group, a phosphoric acid group, an amide group, an amino group, a carbonyl group and a phosphine group.

In order to expand the wavelength band for photoelectric conversion as much as possible and to increase the conversion efficiency, two or more kinds of dyes can be used together or mixed. In this case, the dyes used together or mixed can be selected so that the target wavelength band and intensity distribution of a light source will be adjusted.

### <Charge Transfer Layer>

A charge transfer layer is a layer containing a charge transporting material which has a function to supply an electron to an oxidized dye. The following can be cited as examples of the typical charge transporting material which can be used in the present invention: an electrolyte, such as a solvent which is dissolved a redox ion pair in it, and a nomial temperature molten-salt containing a redox ion pair; a gel type semi-solid electrolyte which is immersed a solution of a redox ion pair to a polymer matrix or a low molecular gel forming agent; and a polymer solid electrolyte. Moreover, other than the charge transporting material in which an ion is concerned, there can be also cited an electron transport material or a positive hole (hole) transport material as a material which is related with electric conduction, and these can also be used in combination with others.

When an electrolyte is used in a charge transfer layer, a redox ion pair to be contained in the electrolyte will not be limited in particular if they can be used in a well-known solar cell.

Specifically, the following ion pairs can be cited: a mixture containing a redox ion pair, such as I³¹/I₃⁻ systemand Br₂⁻/Br₃⁻ system; a metal redox system of a metal complex, such as a ferrocyanic acid salt/ferricyanic acid salt, ferrocene/ferricinium ion or a cobalt complex; an organic redox system, such as alkyl thiol alkyl disulfide, a viologen dye, hydroquinone/quinone; and a sulfur compound, such as poly sodium sulfide, alkyl thiol/alkyl disulfide.

The following combinations are more specifically cited as an iodine system: a combination of iodine with a metal iodide such as Lil, Nal, KI, CsI or CaI₂³¹ ; and a combination of a quaternary ammonium or a quaternary imidazolium (such as tetraalkyl ammonium iodide, pyridinium iodide and imidazolium iodide) with an iodine salt. The following combinations are more specifically cited as a bromine system: a combination of bromine with a metal bromide such as LiBr, NaBr, KBr, CsBr, or CaBr₂; a combination ofbromide with a quaternary ammonium bromide such as tetraalkyl ammonium bromide, or a pyridinium bromide picture.

As a solvent, it is preferable that the solvent is electrochemically inert, and can improve ionic mobility by having a low viscosity, and exhibits outstanding ion conductivity by having a high dielectric constant to improve an effective carrier concentration.

Specifically, the following compounds can be used: carbonate compounds such as dimethyl carbonate, diethyl carbonate, ethylene carbonate and propylene carbonate; heterocyclic compounds such as 3-methyl-2-oxazolidine; ether compounds such as dioxane and diethyl ether; chain ethers such as ethylene glycol dialkyl ether, the propylene glycol dialkyl ether, the polyethylene glycols dialkyl ether and polypropylene glycol dialkyl ether; alcohols such as methanol, ethanol, ethylene glycol mono-alkyl ether, propylene glycol mono-alkyl ether, polyethylene glycols mono-alkyl ether and polypropylene glycol mono-alkyl ether; polyhydric alcohols such as ethylene glycol, diethylene glycol, triethylene glycol, polyethylene glycols, propylene glycol, polypropylene glycol and glycerine; nitrile compounds such as acetonitrile, glutalodinitrile, propionitrile, methoxypropionitrile, methoxyacetonitrile and benzonitrile; and aprotic polar substances such as tetrahydrofiiran, dimethyl sulfoxide and sulfolane.

A preferable concentration of an electrolyte is from 0.1 to 15 M, and more preferably it is from 0.2 to 10 M. In the case of using an iodine system, the preferable addition concentration of iodine is from 0.01 to 0.5 M.

A molten-salt electrolyte is preferable from a viewpoint of compatibility of photoelectric conversion efficiency and durability. Examples of a molten-salt electrolyte are electrolyte containing a known iodide salt of pyridinium, imidazolium or triazolium described in: WO 95/18456, JP-A No. 8-259543, JP-A No. 2001-357896, Electrochemistry, volume 65, No. 11, page 923 (1997). It is preferable that these molten-salt electrolytes are in a molten state at normal temperature, it is more preferable not to use a solvent with them.

It is possible to use a material in which an electrolyte or an electrolytic solution is contained in a matrix of an oligomer and a polymer. It can also be used after gelation (semi-solidifying) with a polymer addition, an addition of a low molecular gelating agent or an oil gelating agent, polymerization of a multi functional monomer, or a cross linkage reaction of a polymer.

When gelation is carried out by addition of a polymer, especially polyacrylonitrile and polyvinylidene fluoride can be used preferably. When gelation is carried out by addition of an oil gelating agent, a desirable compound is a compound which has an amide structure in the molecular structure. Moreover, when gelation is carried out for an electrolyte via the cross linkage reaction of a polymer, it is preferable to use together both a polymer having a cross-linkable reactive group and crosslinking agent. In this case, preferable examples of a cross-linkable reactive group include: a nitrogen-containing heterocycle (for example, a pyridine ring, an imidazole ring, a thiazole ring, an oxazole ring, a triazole ring, a morpholine ring, a piperidine ring and a piperazine ring), and examples of a preferable crosslinking agent include: a reagent having two or more functional groups which can make an electrophilic reaction to a nitrogen atom (for example, alkyl halide, aralkyl halide, sulfonic cid ester, acid anhydride, acid chloride and isocyanate). The concentration of the electrolyte is usually from 0.01 to 99 weight %, and it is preferably about 0.1 to 90 weight %.

Moreover, as a gel electrolyte, an electrolyte composition containing an electrolyte, a metallic oxide particle, and/or a conductive particle can also be used. As a metal oxide particle, one sort or a mixture of two or more sorts chosen from the following group are cited: TiO₂, SnO₂, WO₃, ZnO, ITO, BaTiO₃, Nb₂O5, In₂O₃, ZrO₂, Ta₂O₅, La₂O₃, SrTiO₃, Y₂O₃, Ho₂O₃, Bi₂O₃, CeO₂ and Al₂O₃. These may be compounds doped with an impurity, or a composite oxide. As a conductive particle, a substance mainly composed of carbon is cited.

Next, a polyelectrolyte is a solid substance which can dissolve a redox species or which can make a bond with at least one substance which constitutes a redox species. Preferable examples of a polyelectrolyte include: a polymer or a cross-linked polymer, such as polyethylene oxide, polypropylene oxide, polyethylene succinate, poly-β-propiolactone, polyethylene imine and polyalkylene sulfide; a compound prepared by adding a polyether segment or an oligoalkylene oxide structure as a side chain to a polymer functional group (for example, polyphosphazene, polysiloxane, polyvinyl alkohol, polyacrylic acid and polyalkylene oxide), and also the copolymer of the compound. Among them, preferable are a compound having an oligoalkylene oxide structure as a side chain and a compound having a polyether segment as a side chain.

In order to incorporate a redox species into the above-mentioned solid, the following methods can be used, for example: a method to polymerize a monomer to become a polymer under the coexistence of a redox species; a method having a step of dissolving a solid of a polymer into a solvent according to need, and, subsequently, the above-mentioned redox species is added to it. The content of a redox species can be suitably selected according to the ionic-conductive property required.

In the present invention, a solid hole transport material prepared by combining an organic compound and an inorganic compound can be used instead of an ion-conductive electrolyte, such as a molten-salt. As an organic hole transport material, the following conducting polymers can be used preferably: aromatic amines, triphenylene derivative, polyacethylene and its derivative, poly(p-phenylene) and its derivative, poly(p-phenylenevinylene) and its derivative, polythenylene vinylene and its derivative, polythiophene and its derivative, polyaniline and its derivative and polytoluidine its derivative.

In a positive hole (hole) transport material, in order to control a dopant level, it may be added a compound containing a cation radical like tris(4-bromophenyl)aluminium hexachloroantimonate. Moreover, in order to perform potential control (compensation of a space charge layer) of an oxide semiconductor surface, it may be added a salt like Li[(CF₃SO₂)₂N]. A p type inorganic compound semiconductor can be used as an inorganic hole transport material.

A p type inorganic compound semiconductor used for this purpose is preferable to have a band gap of 2 eV or more, and also it is more preferable to have a band gap of 2.5 eV or more. The ionization potential of a p type inorganic compound semiconductor is required to be smaller than the ionization potential of a dye adsorbed electrode, when the conditions which can reduce the positive hole of the dye are taken into consideration. Although the preferable range of the ionization potential of a p type inorganic compound semiconductor will change with a dye to be used, it is generally from 4.5 to 5.5 eV, and it is more preferable to be from 4.7 to 5.3 eV.

A preferable p type inorganic compound semiconductor is a compound semiconductor containing a monovalent copper, and CuI and CuSCN are preferable, and further CuI is most preferable. A preferable hall mobility in the charge transfer layer containing a p type inorganic compound semiconductor is 10⁻⁴ to 10⁴m²/V·sec, and more preferably it is 10⁻³ to 10³ m²/V·sec. Moreover, a preferable electric conductivity of a charge transfer layer is 10⁻⁸ to 10²S/cm, and more preferably it is 10⁻⁶ to 10 S/cm.

In the present invention, there is no limitation in particular in the method of forming a charge transfer layer between a semiconductor electrode and a counter electrode. However, the following methods can be used, for example: a method having the step of filling up with the aforesaid electrolytic solution and the various electrolyte between the semiconductor electrode and the counter electrode after locating the both electrodes in a facing position with each other to prepare a charge transfer layer; and a method having the step of after dropping or coating the various electrolytes on the semiconductor electrode or on the counter electrode to prepare a charge transfer layer, piling up the other electrode on the charge transfer layer. Here, a semiconductor electrode is a portion from a conductive base to a metal oxide semiconductor layer.

In order to prevent a leak of an electrolyte from between a semiconductor electrode and a counter electrode, it is preferable to use a film and a resin so as to seal the space between the semiconductor electrode and the counter electrode, or to store both the semiconductor electrode, the charge transfer layer and a counter electrode in a suitable case if needed.

In the former formation method, it can be used an normal pressure process employing a capillary phenomenon by impregnation of a charge transfer layer as a loading method, or it can be used a vacuum process using a lower pressure than a normal pressure and substituting the gas phase of the space with a liquid phase.

In the latter formation method, as a coating method, it can be used, for example, micro gravure coating, dip coating, screen coating and spin coating. In a wet charge transfer layer, a counter electrode will be provided under the condition of undried, and the liquid leakage control treatment of an edge portion will be taken. Moreover, in the case of a gel electrolyte, there is a method of coating with a wet process, and then solidifying by polymerization. In that case, a counter electrode can be given after being dried and solidified.

In the case of a solid positive hole (hole) transporting material or a solid electrolyte, a charge transfer layer can be formed by a dry film forming process such as a vacuum deposition method and a CVD method, and thereafter a counter electrode can be given to it. Specifically, the charge transfer layer can be introduced into the interior of an electrode with the methods, such as a vacuum deposition method, a cast method, a coating method, a spin coat method, a dip coating method, an electrolytic polymerization method and an optical electrolytic polymerization method, and a base is heated at any temperature if needed to evaporating a solvent to prepare the charge transfer layer.

The thickness of a charge transfer layer is preferably 10 μm or less, it is more preferably 5 μm or less, and also it is still more preferably 1 μm or less. The electric conductivity of a charge transfer layer is preferably 1×10⁻¹⁰ S/cm or more, and it is more preferably 1×10⁻⁵ S/cm or more

### <Counter Electrode>

The counter electrode which can be used in the present invention may be a single layer of the base having in itself conductivity like the above-described conductive base, or it may be a base having a conductive layer on the base. In the latter case, the conductive material used for the conductive layer, the base, and their producing methods may be the same as used in the case of the above-described conductive base material. Various well-known materials and methods can be applied for that.

It is preferable to use a substance having catalytic ability with which an oxidation reaction of an I₃⁻ ion and a reduction reaction of other redox ions are perfonned with sufficient speed. Specifically, there are cited: a platinum electrode, a conductive substance having subjected to platinum plating or platinum vacuum evaporation on the surface thereof, a rhodium metal, a ruthenium metal, ruthenium oxide and carbon. Moreover, when a cost aspect and flexibility are taken into consideration like mentioned above, it is also one of the preferable embodiments to use a plastic sheet as a base material and to apply thereon a polymer material as a conductive material.

Although the thickness of a conductive layer is not limited in particular, it is preferably 3 nm to 10 μm. When the conductive layer is metal, the thickness of the metal is preferably 5 μm or less, and more preferably, it is 10 nm to 35 μm. The lower the surface resistivity of a counter electrode, the better it is. Specifically, the range of the surface resistivity is preferable to be below 50 Ω/□, more preferably, it is below 20 Ω/□, still more preferably, it is below 10 Ω/□.

Since a light may be received from one of the conductive base and the counter electrode mentioned above, or from both, it is sufficient that at least one of the conductive base and the counter electrode is substantially transparent. It is preferable to make a conductive base transparent and to introduce a light from the conductive base side from a viewpoint of improvement in electric power generation efficiency. In this case, the counter electrode is preferable to have the nature to reflect a light. As such a counter electrode, glass or plastic which is vapor-deposited with a metal or a conductive oxide, or a metal thin film can be used.

A counter electrode can be made by coating, plating or vapor-depositing (PVD, CVD) with a conductive material directly on the charge transfer layer mentioned above, or by just sticking a conductive base single layer on the conductive layer side of the base. Moreover, as well as in the case of the conductive base, when especially a counter electrode is transparent, it is also one of the preferable embodiments to use together a metallic wiring layer.

The conductive layer as a counter electrode is preferable to have conductivity, and to exhibit a catalytic effect in the reduction reaction of a redox electrolyte. For example, glass or a polymer film on which are vapor-deposited platinum, carbon, rhodium, or ruthenium, or on which is applied conductive particles can be used for that.

### Examples

In the following, the present invention will be described with reference to examples, however, the present invention is not limited thereto.

### Example 1

### [Preparation of Conductive Base]

### <<Preparation of Conductive Base CB-01>>

### <Formation of Under Coat Layer>

On one side of a biaxial stretching PET base support having a thickness of 200 μm was performed a corona discharge treatment with 12 W·min/m². An under coat coating solution B-1 was applied so that it might become a dried layer thickness of 0.1 μm, then a corona discharge treatment of 12 W·min/m² was performed on it, and an under coat coating solution B-2 was applied so that it might become a dried layer thickness of 0.06 μm. Then, a heat treatment was performed at 120° C. for 1.5 minutes to obtain a PET film base support provided with an under coat layer.

(Under coat coating solution B-1)

| | | |
|---|---|---|
| A copolymer latex made by 20 weight parts of styrene, | 50 | g |
| 40 weight parts of glycidyl methacrylate and 40 weight | | |
| parts of butyl acrylate (solid content 30%) | | |
| SnO₂ sol (A) | 440 | g |
| Compound (UL-1) | 0.2 | g |
| Water to make up to | 1,000 | ml |

(Under coat coating solution B-2)

| | | |
|---|---|---|
| Gelatin | 10 | g |
| Compound (UL-1) | 0.2 | g |
| Compound (UL-2) | 0.2 | g |
| Silica particles (an average diameter of 3 μm) | 0.1 | g |
| Hardener (UL-3) | 1 | g |
| Water to make up to | 1,000 | ml |

Preparation of SnO₂ sol (A):

65 g of SnCl₄.5H₂O was dissolved in 2,000 ml of distilled water to obtain a homogeneous solution, subsequently this solution was boiled, and a precipitation was obtained. The obtained precipitation was taken out by decantation and it was repeatedly washed with distilled water. The silver nitrate was dropped into the distilled water which washed the precipitation in order to check that there was no reaction of chlorine ions. After checking that, distilled water was added to the washed precipitation to make us the whole amount to be 2,000 ml. By adding 40 ml of 30% aqueous ammonia solution to this and then by heating, a uniform sol was obtained. Furthermore, by adding an aqueous ammonia solution, heating concentration was carried out until the solids concentration of SnO₂ became 8.3 weight %. Thus SnO₂ sol (A) was obtained.

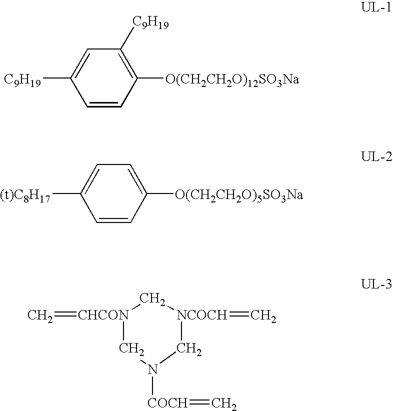

### <Preparation of Silver Halide Fine Grain Emulsion EMP-1>

The following Solution-A was kept at 34° C. in a reaction vessel, a pH value of the solution was adjusted to 2.95 using nitric acid (concentration of 6%) while agitating at high speed using agitation mix apparatus disclosed in JP-A No. 62-160128. Then, there were added using a double-jet precipitation method the following (Solution-B) and the following (Solution-C) for 8 minutes and 6 seconds at a fixed amount of flow. After termination of the addition, sodium carbonate (concentration of 5%) was used to adjust a pH value to be 5.90, subsequently the followings (Solution-D) and (Solution-E) were added.

After the above-mentioned processes were finished, desalting and rinsing treatments were performed using the flocculation method in accordance with the conventional method at 40° C. Then, the following (Solution-F) and a fungicide were added, and the mixture was dispersed at 60° C., then a pH value was adjusted to 5.90 at 40° C. In this way, it was obtained silver chlorobromide cubic fine grain emulsion (EMP-1) containing a silver bromide content of 10 mol %, having an average grain diameter of 0.09 μm and a coefficient of variation of 10%.

(Solution-A)

| | | |
|---|---|---|
| Alkali processed inert gelatin (average molecular | 18.7 | g |
| weight of 100,000) | | |
| Sodium chloride | 0.31 | g |
| (Solution-I) described below | 1.59 | ml |
| Pure water | 1,246 | ml |

(Solution-B)

| | | |
|---|---|---|
| Silver nitrate | 169.9 | g |
| Nitric acid (concentration of 6%) | 5.89 | ml |
| Water to make up to 317.1 ml | | |

(Solution-C)

| | | |
|---|---|---|
| Alkali processed inert gelatin (average molecular | 5.66 | g |
| weight of 100,000) | | |
| Sodium chloride | 58.8 | g |
| Potassium bromide | 13.3 | g |
| (Solution-I) described below | 0.85 | ml |
| (Solution-II) described below | 2.72 | ml |
| Pure water to make up to 317.1 ml | | |

(Solution-D)

| | | |
|---|---|---|
| 2-Methyl-4-hydroxy-1,3,3a,7-tetraazaindene | 0.56 | g |
| Pure water | 112.1 | ml |

(Solution-E)

| | | |
|---|---|---|
| Alkali processed inert gelatin (average molecular | 3.96 | g |
| weight of 100,000) | | |
| (Solution-I) described below | 0.40 | ml |
| Pure water | 128.5 | ml |

(Solution-I)

Surfactant: 10 weight % of methanol solution of
polyisopropylene polyethyleneoxy-disucccinic
acid aster sodium salt

(Solution-II)

10 weight % of aqueous solution of hexachloro
rhodium complex.

(Solution-F)

| | | |
|---|---|---|
| Alkali processed inert gelatin (average molecular | 16.5 | g |
| weight of 100,000) | | |
| Pure water | 139.8 | ml |

### <Preparation of Photosensitive Material 101>

On the base support which was provided with the under coat layer as mentioned above, the silver halide fine grain emulsion EMP-1 prepared as mentioned above was coated so that the coating weight of silver may become 0.8 g/m² by silver conversion, and then it was dried to produce Photosensitive material 101.

In addition, in production of the Photosensitive material 101, a hardener (tetrakis(vinylsulfonylmethyl) methane) was added in an amount of 50 mg per 1 g of gelatin. Moreover, a surfactant (sulfosuccinic acid di(2-ethylhexyl) sodium) was added as a coating aid, and a surface tension was adjusted. The amount of gelatin was adjusted so that the volume ratio of silver to gelatin might be set to 0.5. The aforesaid volume ratio of silver to gelatin indicates a value obtained from the volume of the coated silver halide fine grains divided by the volume of the coated gelatin.

### <Formation of Metallic Current Collecting Layer>

The Photosensitive material 101 produced as described above was subjected to light exposure with a UV ray lamp through a photo mask having a grid made of lines having a width of 13 μm and an interval of lines of 500 μm. Subsequently, after performing a development processing at 35° C. for 30 seconds using the following developer (DEV-1), a fixing treatment was made at 30° C. for 60 seconds using the following fixer (FIX-1), and a rinsing treatment was performed after it. Furthermore, using the following physical developer (PD-1), a physical development was performed at 30° C. for 5 minutes, subsequently a rinsing treatment was performed.

(DEV-1: Developer)

| | | |
|---|---|---|
| Pure water | 500 | ml |
| Metol | 2 | g |
| Anhydrous sodium sulfite | 80 | g |
| Hydroquinone | 4 | g |
| Borax | 4 | g |
| Sodium thiosulfate | 10 | g |
| Potassium bromide | 0.5 | g |
| Water to make up to 1 L in total | | |

(FIX-1: Fixer)

| | | |
|---|---|---|
| Pure water | 750 | ml |
| Sodium thiosulfate | 250 | g |
| Anhydrous sodium sulfite | 15 | g |
| Glacial acetic acid | 15 | ml |
| Potash alum | 15 | g |
| Water to make up to 1 L in total | | |

(PD-1: Physical developer)

| | | |
|---|---|---|
| Pure water | 800 | ml |
| Citric acid | 31 | g |
| Hydroquinone | 7.8 | g |
| Disodium hydrogen phosphate | 1.1 | g |
| Aqueous ammonia solution (28%) | 2.2 | ml |
| Silver nitrate | 1.5 | g |
| Water to make up to 1 L in total | | |

### <Formation of Transparent Conductive Layer>

As a conductive polymer, a water-based dispersion of conductive polyaniline containing a sulfonic acid system dopant (ORMECON D1033W, made by ORMECON Ltd. in Germany) was used. It was coated smoothly on the opening portion of the metallic collecting layer and on the metal thin wires so that the thickness of the dried coating on the silver thin lines might be set to 100 nm. Subsequently, a heat treatment was performed at 100° C. for 20 minutes to obtain Conductive base CB-01.

### <<Preparation of Conductive Base CB-02>>

Conductive base CB-02 was prepared in the same manner as preparation of the Conductive base CB-01 except that the formation of the transparent conductive layer was excluded from the preparation processes.

### <<Preparation of Conductive Base CB-03>>

The water-based dispersion (ORMECON D1033W, made by ORMECON Ltd. in Germany) was coated on the aforesaid PET film base support provided with the under coat layer so that the thickness of the dried coating might be set to 100 nm. Subsequently, a heat treatment was performed at 100° C. for 20 minutes to obtain Conductive base CB-03.

### <<Preparation of Conductive Base CB-04>>

Conductive base CB-04 was prepared in the same manner as preparation of the Conductive base CB-01 except that a water-based dispersion of tin oxide doped with indium was used for forming the transparent conductive layer instead ofusing the water-based dispersion of conductive polyaniline.

### <<Preparation of Conductive Base CB-05>>

Conductive base CB-05 was prepared in the same manner as preparation of the Conductive base CB-01 except that a photo mask having a grid made of lines having a width of 7 μm was used for light exposure with a UV ray lamp in the formation step of a metallic current collecting step.

### [Preparation of Dye-Sensitized Solar Cell]

### <<Preparation of Dye-Sensitized Solar Cell SC-01>>

On Conductive base CB-01 was coated several times a TiO₂ past (Ti-Nanoxide T, made by Solaronix Ltd.) so that the dried layer thickness might become 10 μm and the magnitude of the 4 mm×4 mm square. Then, using the press molding machine, it was stuck by pressure with the conditions of 130° C. and 9.8×10⁸ Pa for 1 minute, and the porous metal oxide semiconductor layer was formed.

In 200 weight parts of a solution of acetonitrile and t-butanol (mixing ratio of 1:1) was dissolved 0.1 weight parts of Dye 2-1 to obtain a dye solution. The above-described metal oxide semiconductor layer provided on the base was immersed in this dye solution for 24 hours. Then, it was washed with a solution of acetonitrile and t-butanol (mixing ratio of 1:1) and was dried to obtain a semiconductor electrode in which the dye was adsorbed to the metal oxide semiconductor layer.

As a counter electrode, a conductive film having a sheet resistance of 0.8 Ω/□ was used. The conductive film was made of a polyethylene terephthalate (PET) film having a thickness of 400 μm and a sheet resistance of 15 Ω/□ which supported ITO as a conductive film and was covered with a platinum film having a thickness of 10 nm with a sputtering process on the surface of ITO.

The above-mentioned semiconductor electrode and the above-mentioned counter electrode were pasted together so that it might face each other using a sheet-like spacer-cum- sealing agent (SX-1170-25, made by Solaronix Ltd.) having a thickness of 25 μm and a hole of 6.5 mm squares. From the electrolyte injection hole prepared in the cathode electrode, there was poured a charge transfer layer containing a redox electrolyte made of lithium iodide, iodine, 1,2-dimethyl-3-propylimidazolium iodide and t-butylpyridine dissolved in acetonitrile so that each concentration might be set to 0.1 mol/L, 0.05 mol/L, 0.6 mol/L and 0.5 mol/L. Then, the hole was blocked with a hot bond, and was sealed using the above-mentioned sealing agent from the top. On the light receiving surface of the base material having the above-mentioned metal oxide semiconductor layer was pasted an anti-reflection film (hard coat/anti-reflection type cellulose film, made by Konica Minolta Opto Inc.). Thus Dye-sensitized solar cell SC-01 was prepared.

### <<Preparation of Dye-Sensitized Solar Cell SC-02>>

### <Preparation of Metal Oxide Interlayer>

A metal oxide interlayer was formed by the aerosol deposition method using the apparatus disclosed in JP-A No. 2004-256920. The metal oxide interlayer was formed on Conductive base CB-02 having a magnitude of 4 mm×4 mm square and made of titanium oxide. The layer thickness was 172 μm and the porous ratio was 16%.

<Manufacturing Process after Formation of a Metal Oxide Semiconductor Layer>

Dye-sensitized solar cell SC-02 was prepared in the same manner as preparation of Dye-sensitized solar cell SC-01 except that the titanium oxide paste for metal oxide semiconductor layer formation was coated on the above-described metal oxide interlayer instead of on the conductive base.

### <<Preparation of Dye-Sensitized Solar Cells SC-03 to SC-11>>

Dye-sensitized solar cells SC-03 to SC-11 were prepared in the same manner as preparation of Dye-sensitized solar cell SC-02 except that the thickness and the porous ratio of the conductive base and the metal oxide interlayer used were changed as shown in Table 1. In addition, the porous ratio of the metal oxide interlayer was controlled by adjusting the gas pressure of a gas bomb and the amount of exhaust air of a vacuum pump.

### <<Preparation of Dye-Sensitized Solar Cell SC-12>>

Dye-sensitized solar cell SC-12 was prepared in the same manner as preparation of Dye-sensitized solar cell SC-11 except that the composition of the metal oxide interlayer was changed into niobium oxide (average grain diameter; 92 nm) from titanium oxide.

### (Evaluation of Photoelectric Conversion Characteristic of Solar Cells)

The solar cells SC-01 to SC-13 obtained above were each irradiated with a solar simulator (low energy spectral sensitivity measuring apparatus CEP-25, made by JASCO (JASCO Corporation)). The light strength of irradiation was 100 mW/m². By irradiation with the light, short circuit current density Jsc (mA/cm²), open circuit voltage value Voc(V), file factor ff, and conversion efficiency η(%) were measured. They are shown in Table 1. The shown values are a mean value of the measurement results which were obtained from every three solar cells of the same composition and the same production ways.

### (Durability Evaluation of Solar Cells)

The solar cells SC-01 to SC-13 obtained above were each subjected to the change of temperature and relative humidity (from −40° C. to 90° C., 85% of RH) in five cycles. This method corresponded to the temperature-humidity resistance test based on A-2 of JIS C893. The photoelectric conversion efficiencies η(%) before and after the temperature—humidity changes were obtained from each solar cell with the above-mentioned measuring method. The results are shown in Table 1. The shown values are a mean value of the measurement results which were obtained from every three solar cells of the same composition and the same production ways.

TABLE 1

| | | | Aperture | | | | | | | | | | |
|---|---|---|---|---|---|---|---|---|---|---|---|---|---|
| | | Line | ratio | | | | | | | | | | |
| | | width of | of metallic | | | | | Open | Short | | | | |
| | | metallic | current | | Metal oxide interlayer | | | circuit | circuit | | | | |
| | Con- | fine | collecting | Transparent | | Layer | Porous | voltage | current | File | Conversion | Dura- | |
| | ductive | wire | layer | conductive | Com- | thickness | ratio | value | density | factor | efficiency | bility | |
| Sample | base | (μm) | (%) | layer | position | (μm) | (%) | (V) | (mA) | (%) | (%) | (%) | Remarks |
| SC-01 | CB-01 | 14 | 94 | Polyaniline | — | — | — | 0.63 | 9.06 | 0.60 | 3.4 | 68 | Comparison |
| SC-02 | CB-02 | 14 | 94 | — | Titanium | 172 | 16 | 0.68 | 8.44 | 0.62 | 3.6 | 72 | Comparison |
| | | | | | Oxide | | | | | | | | |
| SC-03 | CB-03 | — | — | Polyaniline | Titanium | 172 | 16 | 0.69 | 8.05 | 0.63 | 3.5 | 74 | Comparison |
| | | | | | Oxide | | | | | | | | |
| SC-04 | CB-04 | 14 | 94 | ITO | Titanium | 172 | 16 | 0.69 | 8.65 | 0.63 | 3.8 | 83 | Comparison |
| | | | | | Oxide | | | | | | | | |
| SC-05 | CB-01 | 14 | 94 | Polyaniline | Titanium | 172 | 16 | 0.69 | 10.51 | 0.66 | 4.8 | 87 | Present |
| | | | | | Oxide | | | | | | | | invention |
| SC-06 | CB-05 | 8 | 97 | Polyaniline | Titanium | 172 | 16 | 0.70 | 12.18 | 0.67 | 5.7 | 89 | Present |
| | | | | | Oxide | | | | | | | | invention |
| SC-07 | CB-01 | 14 | 94 | Polyaniline | Titanium | 65 | 16 | 0.68 | 12.12 | 0.67 | 5.5 | 86 | Present |
| | | | | | Oxide | | | | | | | | invention |
| SC-08 | CB-01 | 14 | 94 | Polyaniline | Titanium | 172 | 7 | 0.71 | 12.03 | 0.66 | 5.6 | 91 | Present |
| | | | | | Oxide | | | | | | | | invention |
| SC-09 | CB-01 | 14 | 94 | Polyaniline | Titanium | 65 | 7 | 0.73 | 12.07 | 0.66 | 5.8 | 90 | Present |
| | | | | | Oxide | | | | | | | | invention |
| SC-10 | CB-05 | 8 | 97 | Polyaniline | Titanium | 65 | 16 | 0.69 | 12.70 | 0.69 | 6.0 | 87 | Present |
| | | | | | Oxide | | | | | | | | invention |
| SC-11 | CB-05 | 8 | 97 | Polyaniline | Titanium | 65 | 7 | 0.69 | 12.89 | 0.70 | 6.2 | 90 | Present |
| | | | | | Oxide | | | | | | | | invention |
| SC-12 | CB-05 | 8 | 97 | Polyaniline | Niobium | 65 | 7 | 0.72 | 12.91 | 0.69 | 6.4 | 91 | Present |
| | | | | | oxide | | | | | | | | invention |

As are clearly shown by Table 1, Dye-sensitized solar cells SC-05 to SC-12 each exhibited improved Conversion efficiency by increasing Short circuit current density. Especially, remarkable improvement was confirmed by controlling to optimize a layer thickness and a porous ratio of a metal oxide interlayer.

On the other hand, among comparative samples, especially Dye-sensitized solar cell SC-04 incorporated inorganic oxide particles as a conductive material of a transparent conductivity layer exhibited inferior conversion efficiency. It used the resin film as a base material, the conductivity of the transparent conductive layer becomes insufficient, and sufficient large conversion efficiency has not been acquired. In contrast, the dye-sensitized solar cell of the present invention exhibited excellent photoelectric conversion efficiency even when it was calcined at low temperature. It is clear that the dye-sensitized solar cell of the present invention excels in the aptitude of using a resin film base material.

1. A dye-sensitized solar cell comprising a conductive base having thereon a metal oxide semiconductor layer composed of a semiconductor film which is adsorbed a dye on a surface of the semiconductor film; a charge transfer layer; and a counter electrode in that order,
wherein a metal oxide interlayer composed of metal oxide particles is provided between the conductive base and the metal oxide semiconductor layer, and the conductive base comprises a transparent base having thereon a metallic current collecting layer composed of metallic fine wires and a transparent conductive layer containing a conductive polymer.

2. The dye-sensitized solar cell of claim 1,
wherein the metallic thin wire has a width of 5 μm to 20 μm, and the metallic current collecting layer has an aperture ration of 93% to 98%.

3. The dye-sensitized solar cell of claim 1,
wherein the transparent conductive layer covers an aperture portion of the metallic current collecting layer and an upper portion of the metallic thin wires, and the uppermost surface of the conductive base is smooth.

4. The dye-sensitized solar cell of claim 1,
wherein the metal oxide interlayer has a thickness of 5 nm to 200 nm.

5. The dye-sensitized solar cell of claim 1,
wherein the metal oxide interlayer has a porous ratio of 10% or less.
